(19) United States
(12) Patent Application Publication
(10) Pub. No.: US 2025/0211916 A1
(43) Pub. Date: Jun. 26, 2025

(54) VIBRATION DRIVING APPARATUS

(71) Applicant: LG Display Co., Ltd., Seoul (KR)

(72) Inventors: Sooyoun Kim, Paju-si (KR); JounHo Lee, Paju-si (KR); YongWoo Lee, Paju-si (KR); HwaYoul Lee, Paju-si (KR); Uihyeon Jeong, Paju-si (KR); Dae-su Kim, Paju-si (KR)

(73) Assignee: LG Display Co., Ltd., Seoul (KR)

(21) Appl. No.: 18/913,001

(22) Filed: Oct. 11, 2024

(30) Foreign Application Priority Data
Dec. 22, 2023 (KR) 10-2023-0189984

(51) Int. Cl. H04R 17/00; H03F 3/183; H04R 3/00

(52) U.S. Cl. CPC H04R 17/00; H04R 3/00; H03F 3/183; H03F 2200/03

(57) ABSTRACT

A vibration driving apparatus may include a vibration member and a vibration apparatus disposed at a rear surface of the vibration member to vibrate the vibration member according to a driving signal. The driving signal may be an alternating current (AC) signal of 0 V or more.

### CROSS-REFERENCE TO RELATED APPLICATION

This application claims the benefit of and priority to Korean Patent Application No. 10-2023-0189984, filed on Dec. 22, 2023, which is hereby incorporated by reference as if fully set forth herein.

### BACKGROUND

### Field

The present disclosure relates to a vibration driving apparatus.

### Discussion of the Related Art

Recently, the demands for slimmer and thinner electronic devices are increasing. In speakers applied to electronic devices, piezoelectric devices capable of being implemented with a thin thickness are attracting much attention instead of voice coils, based on the demands for slimmer and thinner devices.

Speakers or vibration apparatuses that include a piezoelectric device may be supplied with a driving power or a driving signal through a signal cable and may be driven or may vibrate.

### SUMMARY

The inventors have recognized the following problems occurring when a developed piezoelectric device is practically applied.

The piezoelectric device includes a piezoelectric material. Pb(Zr, Ti)O₃ (PZT)-based materials have a high piezoelectric characteristic, and thus, are used as the piezoelectric material. However, lead (Pb) is a material having strong toxicity and has high volatility in a sintering process, and due to this, causes serious environmental pollution.

Therefore, because a PZT piezoelectric material occupying the most of piezoelectric materials causes an environmental pollution problem, it is required to develop a Pb-free piezoelectric material. The Pb-free piezoelectric material has a low piezoelectric characteristic compared to the PZT piezoelectric material, and thus, a high piezoelectric characteristic is needed.

An aspect of the present disclosure is directed to providing a piezoelectric material composition which may not include lead and may have a high piezoelectric characteristic.

An aspect of the present disclosure may drive a vibration apparatus by using a unipolar method and may thus provide a vibration driving apparatus which has a high piezoelectric characteristic and is capable of the self-poling of a piezoelectric characteristic.

Additional features, advantages, and aspects of the present disclosure are set forth in part in the present disclosure and will also be apparent from the present disclosure or may be learned by practice of the inventive concepts provided herein. Other features, advantages, and aspects of the present disclosure may be realized and attained by the structure particularly pointed out in the present disclosure, or derivable therefrom, and claims hereof as well as the appended drawings.

To achieve these and other advantages and aspects of the present disclosure, as embodied and broadly described herein, in one or more aspects, a vibration driving apparatus comprises a vibration member, and a vibration apparatus disposed at a rear surface of the vibration member to vibrate the vibration member according to a driving signal. The driving signal is an alternating current (AC) signal of 0 V or more.

According to an aspect of the present disclosure, a vibration driving apparatus which does not include lead (Pb) and has a high piezoelectric characteristic may be provided.

According to an aspect of the present disclosure, because a piezoelectric material composition does not include Pb, a production restriction material may be reduced and replacement of a harmful material may be implemented, and thus, an environment-friendly piezoelectric material composition may be provided.

According to an aspect of the present disclosure, a piezoelectric device may be driven by a unipolar method, and thus, a vibration driving apparatus capable of the self-poling of a piezoelectric characteristic may be provided.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate aspects of the disclosure and together with the description serve to explain the principle of the disclosure. In the drawings:

FIG. 1 is a diagram illustrating a vibration apparatus according to an aspect of the present disclosure;

FIG. 2 is a cross-sectional view taken along line A-A′ illustrated in FIG. 1 according to an aspect of the present disclosure;

FIG. 3 is a cross-sectional view taken along line B-B′ illustrated in FIG. 1 according to an aspect of the present disclosure;

FIG. 4 is a diagram illustrating a driving circuit according to an aspect of the present disclosure;

FIG. 5 is a diagram illustrating a method of manufacturing a vibration apparatus according to an aspect of the present disclosure;

FIG. 6 is a diagram illustrating a graph of an electric field and poling of a vibration apparatus according to an aspect of the present disclosure;

FIGS. 7A to 7D are diagrams illustrating bipolar driving reliability with respect to a temperature of a vibration apparatus according to an experiment example of the present disclosure;

FIGS. 8A and 8B are diagrams illustrating a sound pressure level with respect to a frequency of a vibration apparatus according to an experiment example of the present disclosure;

FIGS. 9A to 9C are diagrams illustrating a sound pressure level with respect to a frequency of a vibration apparatus according to an aspect of the present disclosure;

FIGS. 10A and 10B are diagrams illustrating a sound pressure level in a full frequency domain of a vibration apparatus according to an aspect of the present disclosure;

FIGS. 11A and 11B are diagrams illustrating a sound pressure level with respect to a driving time of a piezoelectric device according to an aspect of the present disclosure;

FIG. 12 is a diagram illustrating an automotive sound apparatus according to an aspect of the present disclosure;

FIG. 13 is a perspective view of a display apparatus according to an aspect of the present disclosure; and

FIG. 14 is a cross-sectional view taken along line I-I′ illustrated in FIG. 13 according to an aspect of the present disclosure.

### DETAILED DESCRIPTION

Reference is now made in detail to aspects of the present disclosure, examples of which may be illustrated in the accompanying drawings. In the following description, when a detailed description of well-known methods, functions, structures or configurations may unnecessarily obscure aspects of the present disclosure, a detailed description of such known functions or configurations may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the aspects described with reference to the accompanying drawings. The present disclosure may, however, be embodied in different forms and should not be construed as limited to the example aspects set forth herein. Rather, these example aspects are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

Where the term “comprise,” “have,” “include,” “contain,” “constitute,” “made of,” “formed of,” “composed of,” or the like is used with respect to one or more elements (e.g., layers, films, regions, components, sections, members, parts, regions, areas, portions, steps, operations, and/or the like), one or more other elements may be added unless a term such as “only” or the like, is used. The terms used in the present disclosure are merely used in order to describe example aspects, and are not intended to limit the scope of the present disclosure. The terms of a singular form may include plural forms unless the context clearly indicates otherwise.

The word “exemplary” is used to mean serving as an example or illustration, unless otherwise specified. Aspects are example aspects. “Aspects,” “examples,” “aspects,” and the like should not be construed as preferred or advantageous over other implementations. An aspect, an example, an example aspect, an aspect, or the like may refer to one or more aspects, one or more examples, one or more example aspects, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

In describing a positional relationship, when the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of,” or the like, one or more other parts may be located between the two parts unless a more limiting term, such as “immediate(ly),” “direct(ly),” or “close(ly),” is used. For example, where a structure is described as being positioned “on,” “upon,” “on top of,” “over,” “under,” “above,” “below,” “beneath,” “near,” “close to,” “adjacent to,” “beside,” “next to,” “at or on a side of,” or the like another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, may be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, may include all directions of “above” and “below.” Likewise, an exemplary term “above” or “on” may include both directions of “above” and “below.”

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

It is understood that, although the terms “first,” “second,” or the like may be used herein to describe various elements (e.g., layers, films, regions, components, sections, members, parts, regions, areas, portions, steps, operations, and/or the like), these elements should not be limited by these terms, for example, to any particular order, sequence, precedence, or number of elements. These terms are used only to distinguish one element from another. For example, a first element could be termed a second element, and, similarly, a second element could be termed a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, or the like) is described as “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The phrase that an element (e.g., layer, film, region, component, section, or the like) is “provided,” “disposed,” “connected,” “coupled,” or the like in, on, with or to another element may be understood, for example, as that at least a portion of the element is provided, disposed, connected, coupled, or the like in, on, with or to at least a portion of another element, or that the entirety of the element is provided, disposed, connected, coupled, or the like in, on, with or to another element. The phrase that an element (e.g., layer, film, region, component, section, or the like) “contacts,” “overlaps,” or the like with another element may be understood, for example, as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other. Such terms may mean a wider range of lines or directions within which the components of the present disclosure can operate functionally. For example, the terms “first direction,” “second direction,” and the like, such as a direction parallel or perpendicular to “x-axis,” “y-axis,” or “z-axis,” should not be interpreted only based on a geometrical relationship in which the respective directions are parallel or perpendicular to each other, and may be meant as directions having wider directivities within the range within which the components of the present disclosure may operate functionally.

The term “at least one” should be understood as including any and all combinations of one or more of the associated listed items. For example, each of the phrases of “at least one of a first item, a second item, or a third item” and “at least one of a first item, a second item, and a third item” may represent (i) a combination of items provided by one or more of the first item, the second item, and the third item or (ii) only one of the first item, the second item, and the third item.

The expression of a first element, a second elements, “and/or” a third element should be understood to encompass one of the first, second, and third elements, as well as any and all combinations of the first, second and third elements. By way of example, A, B and/or C encompass only A; only B; only C; any of A, B, and C (e.g., A, B, or C); or some combination of A, B, and C (e.g., A and B; A and C; or B and C); and all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as different from one another. In another example, an expression “different from one another” may be understood as different from each other. In one or more examples, the number of elements involved in the foregoing expression may be two. In one or more examples, the number of elements involved in the foregoing expression can be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various aspects of the present disclosure may be partially or entirely coupled to or combined with each other, may be technically associated with each other, and may be operated, linked, or driven together in various ways. Aspects of the present disclosure may be implemented or carried out independently of each other, or may be implemented or carried out together in a co-dependent or related relationship. In one or more aspects, the components of each apparatus according to various aspects of the present disclosure may be operatively coupled and configured.

Unless otherwise defined, the terms (including technical and scientific terms) used herein have the same meaning as commonly understood by one of ordinary skill in the art to which example aspects belong. It should be further understood that terms, such as those defined in commonly used dictionaries, should be interpreted as having a meaning that is, for example, consistent with their meaning in the context of the relevant art and should not be interpreted in an idealized or overly formal sense, unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example aspects.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness. Thus, aspects of the present disclosure are not limited to a scale, dimension, size, or thickness illustrated in the drawings.

To solve such a problem, the inventors have developed a vibration driving apparatus which implements a vibration by using a BT-based piezoelectric material as a vibration layer and applying an alternating current (AC) signal of 0 V or more. The BT-based piezoelectric material may be a piezoelectric material including BiTiO₃.

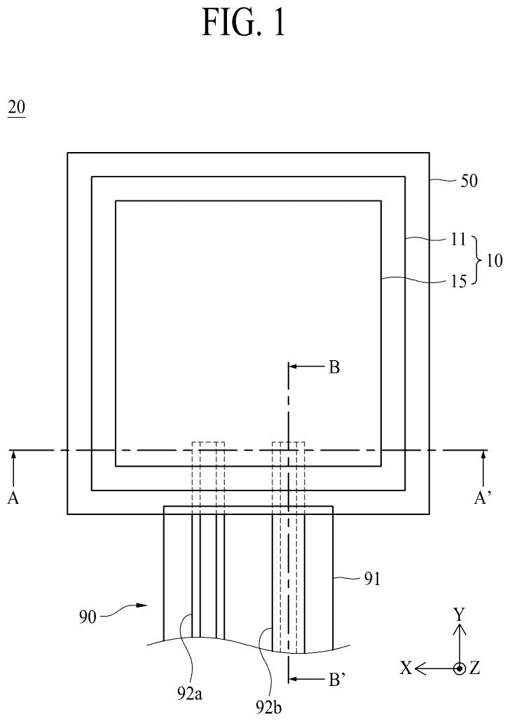

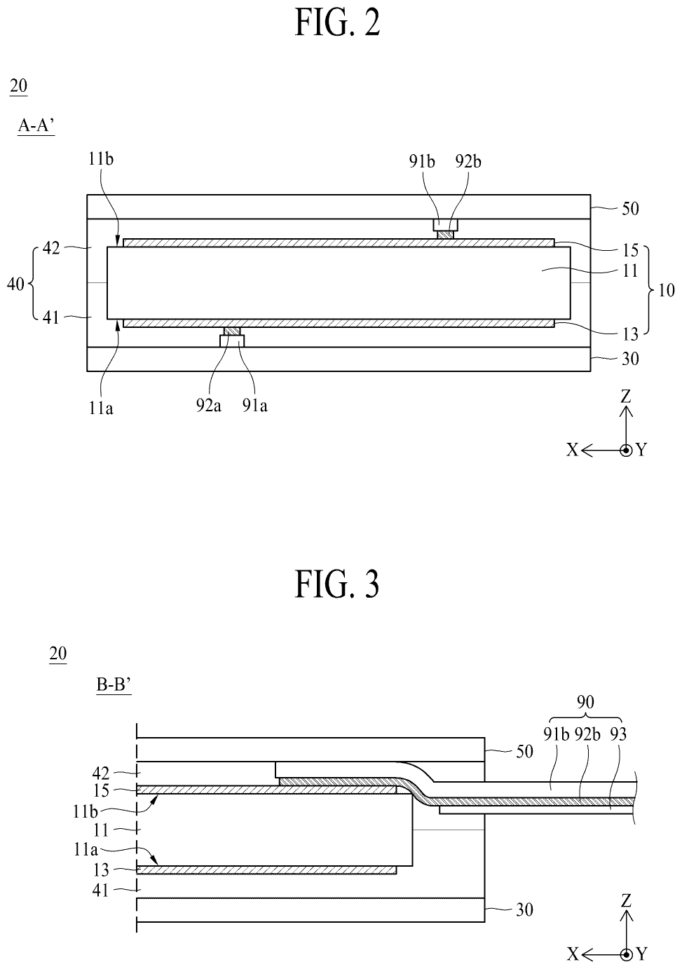

FIG. 1 is a diagram illustrating a vibration apparatus 20 according to an aspect of the present disclosure. FIG. 2 is a cross-sectional view taken along line A-A′ illustrated in FIG. 1 according to an aspect of the present disclosure. FIG. 3 is a cross-sectional view taken along line B-B′ illustrated in FIG. 1 according to an aspect of the present disclosure.

As shown in FIGS. 1 to 3, the vibration apparatus 20 according to an aspect of the present disclosure may include a vibration generating portion 10.

The vibration generating portion 10 may include at least one or more vibration portions. For example, the vibration generating portion 10 according to an example aspect of the present disclosure may have a single-layer structure and may include one vibration portion. For example, the vibration generating portion 10 may be a piezoelectric device, a vibration device, or a vibration portion, but aspects of the present disclosure are not limited thereto.

The vibration generating portion 10 may include a piezoelectric device or a piezoelectric material (or an electroactive material) having a piezoelectric effect. For example, the vibration generating portion 10 may be a piezoelectric device. For example, the piezoelectric material (or the piezoelectric device) may have a characteristic where pressure or twisting is applied to a crystal structure by an external force, a potential difference occurs due to dielectric polarization caused by a relative position change of a positive (+) ion and a negative (−) ion, and a vibration is generated by an electric field based on a voltage applied thereto.

The vibration generating portion 10 may include a vibration layer 11, a first electrode layer 13, and a second electrode layer 15.

The vibration layer 11 may be provided between the first electrode layer 13 and the second electrode layer 15. The vibration layer 11 may include a piezoelectric material (or an electroactive material) having a piezoelectric effect. The vibration layer 11 may include a ceramic-based material for implementing a relatively high vibration, or may include piezoelectric ceramic having a perovskite-based crystal structure. For example, the vibration layer 11 may be a piezoelectric device layer, a piezoelectric material layer, a piezoelectric ceramic layer, a vibration layer, or displacement layer, but aspects of the present disclosure are not limited thereto.

A vibration layer 11 according to an aspect of the present disclosure may include a BT-based piezoelectric material including no lead (Pb). For example, the vibration layer 11 according to an aspect of the present disclosure may include the BT-based piezoelectric material expressed as the following Equation 1. The BT-based piezoelectric material may include barium (Ba), titanium (Ti), and zirconium (Zr).

$$a Ba ( {Ti}_{1 - y} , {Zr}_{y} ) {O}_{3 - b} ( {Ba}_{1 - x} , {Ca}_{x} ) {TiO}_{3} + c mol \% A \qquad [ Equation 1 ]$$

For example, A may be TiO₂, CuO, KF, FeO₃, or NiO, 0.40≤a≤0.60, 0.40≤b≤0.60, 0.00<c≤1.00, 0.05≤x≤0.30, and 0.10≤y≤0.20.

The first electrode layer 13 may be disposed at a first surface (or a lower surface) of the vibration layer 11. The first electrode layer 13 may have the same size as that of the vibration layer 11, or may have a size which is less than that of the vibration layer 11. For example, the first electrode layer 13 may include a single-electrode shape. For example, the first electrode layer 13 may have a tetragonal shape. For example, an end (or a lateral surface or a side surface) of the first electrode layer 13 may be apart from an end (or a lateral surface or a side surface) of the vibration layer 11, and thus, an electrical connection (or short circuit) between the first electrode layer 13 and the second electrode layer 15 may be prevented.

The second electrode layer 15 may be disposed at a second surface (or an upper surface) of the vibration layer 11 that is different from or opposite to the first side. The second electrode layer 15 may have the same size as that of the vibration layer 11, or may have a size which is less than that of the vibration layer 11. For example, the second electrode layer 15 may include a single-electrode shape. For example, the second electrode layer 15 may have a tetragonal shape. For example, an end (or a lateral surface or a side surface) of the second electrode layer 15 may be apart from an end (or a lateral surface or a side surface) of the vibration layer 11, and thus, an electrical connection (or short circuit) between the second electrode layer 15 and the first electrode layer 13 may be prevented.

One or more of the first electrode layer 13 and the second electrode layer 15 according to an example aspect of the present disclosure may include a transparent conductive material, a semitransparent conductive material, or an opaque conductive material. For example, the transparent or semitransparent conductive material may include one or more of indium tin oxide (ITO) or indium zinc oxide (IZO), but aspects of the present disclosure are not limited thereto. The opaque conductive material may include one or more of gold (Au), silver (Ag), platinum (Pt), palladium (Pd), molybdenum (Mo), magnesium (Mg), carbon, or glass frit-including silver (Ag), or an alloy thereof, but aspects of the present disclosure are not limited thereto. For example, carbon may be a carbon material including carbon black, ketjen black, carbon nanotube, and graphite, but aspects of the present disclosure are not limited thereto.

According to another aspect of the present disclosure, each of the first electrode layer 13 and the second electrode layer 15 may include silver (Ag) with low resistance to enhance the electrical characteristics and/or the vibration characteristics of the vibration layer 11.

In the first electrode layer 13 and the second electrode layer 15 including glass frit-including silver (Ag), a content of glass frit may be about 1 wt % or more to about 12 wt % or less, but aspects of the present disclosure are not limited thereto. The glass frit may include a material based on PbO or Bi₂O₃, but aspects of the present disclosure are not limited thereto.

The vibration layer 11 may be polarized (or poling) by a certain voltage applied to the first electrode layer 13 and the second electrode layer 15 in a certain temperature atmosphere or a temperature atmosphere which is changed from a high temperature to a room temperature, but aspects of the present disclosure are not limited thereto.

According to an aspect of the present disclosure, the vibration layer 11 may alternately repeat contraction and/or expansion based on an inverse piezoelectric effect based on a sound signal (or a voice signal) applied to the first electrode layer 13 and the second electrode layer 15 from the outside, and thus, may vibrate. For example, the vibration layer 11 may vibrate based on a vertical-direction vibration and a horizontal-direction vibration by the first electrode layer 13 and the second electrode layer 15. A displacement (or vibration or driving) of a vibration member may increase based on the horizontal-direction contraction and/or expansion of the vibration layer 11, and thus, a vibration of a vibration apparatus may be further enhanced.

The vibration layer 11 according to an aspect of the present disclosure may be poled by an AC signal of 0 V or more. In this case, a peak voltage Vp of the AC signal may have a value of a coercive field Ec of a piezoelectric material. For example, the coercive field Ec of the piezoelectric material included in the vibration layer 11 according to an aspect of the present disclosure may have a value having a range of 1.8 kV/cm to 2.3 kV/cm. For example, the coercive field Ec of the piezoelectric material may denote that a voltage supplied to a thickness of 1 cm of the vibration layer 11 is 1.8 kV to 2.3 kV.

According to an aspect of the present disclosure, a driving voltage V and the peak voltage Vp in bipolar driving and unipolar driving may be calculated by using a coercive field Ec. For example, the bipolar driving may be a method which alternately changes a positive (+) voltage and a negative (−) voltage to perform driving. For example, the unipolar driving may be a method which alternately changes 0 and a positive (+) voltage to perform driving.

According to an aspect of the present disclosure, the vibration layer 11 may have a thickness of 150 μm. For example, when the coercive field Ec of the piezoelectric material is 1.8 kV in thickness of 1 cm, a driving voltage may be 27 V. This may be calculated by using a proportional equation. Therefore, when the coercive field Ec of the piezoelectric material is 1.8 kV/cm, the driving voltage V in bipolar driving may be +13.5 V, and the driving voltage V in unipolar driving may be 27 V. Therefore, when the coercive field Ec of the piezoelectric material is 1.8 kV/cm, the peak voltage Vp in bipolar driving may be 13.5 Vp, and the peak voltage Vp in unipolar driving may be 27 Vp. For example, when the coercive field Ec of the piezoelectric material is 2.3 kV in thickness of 1 cm, the driving voltage may be 34.5 V. When the coercive field Ec of the piezoelectric material is 2.3 kV/cm, the driving voltage V in bipolar driving may be ±17.25 V, and the driving voltage V in unipolar driving may be 33.5 V. Therefore, when the coercive field Ec of the piezoelectric material is 2.3 kV/cm, the peak voltage Vp in bipolar driving may be 17.25 Vp, and the peak voltage Vp in unipolar driving may be 33.5 Vp.

Therefore, the vibration apparatus according to an aspect of the present disclosure may be driven by a unipolar driving method (i.e., an AC signal of 0 V or more), and the peak voltage Vp may be 33.5 Vp or more. Accordingly, the vibration apparatus according to an aspect of the present disclosure may be driven by the unipolar driving method (i.e., the AC signal of 0 V or more), and the peak voltage Vp may have a value having a range of 40 Vp to 60 Vp.

According to an aspect of the present disclosure, in order to replace lead (Pb), a BT-based piezoelectric material which is a lead-free material may be used as the vibration layer 11. The BT-based piezoelectric material may facilitate a manufacturing method and may have a relatively high piezoelectric characteristic in lead-free piezoelectric materials. However, due to a low curie temperature Tc and the coercive field Ec, poling may be easily released in bipolar driving, causing a reduction in reliability of a vibration apparatus.

For example, in bipolar driving, when the driving voltage is lower than the coercive field Ec, there may be only a piezoelectric effect, and poling may not be implemented. For example, in bipolar driving, when the driving voltage is higher than the coercive field Ec, poling may be easily released based on a BT-based domain, causing a reduction in reliability of a vibration apparatus.

An aspect of the present disclosure may use a lead-free BT-based piezoelectric material as the vibration layer 11 so as to replace lead (Pb) and may drive the vibration apparatus by using a unipolar driving method with an AC signal of 0 V or more, instead of bipolar driving. Therefore, an aspect of the present disclosure may drive the vibration apparatus by using the unipolar driving method, and thus, even in a case where the vibration apparatus is driven with a voltage which is greater than or equal to the coercive field Ec, the vibration apparatus may be prevented from being degraded by repeated driving. Accordingly, in an aspect of the present disclosure, a sound pressure level may be self-poled in driving of the vibration apparatus, based on the low curie temperate Tc and the coercive field Ec, and the reliability of the vibration apparatus may be enhanced.

Moreover, an aspect of the present disclosure may drive the vibration apparatus by using the unipolar driving method with the AC signal of 0 V or more and may set the peak voltage Vp of the AC signal to a value which is greater than or equal to the coercive field Ec of a piezoelectric material, and thus, may prevent poling of the vibration apparatus from being depoled and may enhance a sound pressure level of the vibration apparatus.

The vibration device 20 according to an aspect of the present disclosure may further include a first cover member 30 and a second cover member 50.

The first cover member 30 may be disposed at a first surface of the vibration generating portion 10. For example, the first cover member 30 may be configured to cover a lower portion of the vibration generating portion 10. For example, the first cover member 30 may be configured to cover the first electrode layer 13 of the vibration generating portion 10. Accordingly, the first cover member 30 may protect the first surface of the vibration generating portion 10.

The second cover member 50 may be disposed at a second surface of the vibration generating portion 10. The second surface of the vibration generating portion 10 may be different from or opposite to the first surface of the vibration generating portion 10. For example, the second cover member 50 may be configured to cover the second electrode layer 15 of the vibration generating portion 10. Accordingly, the second cover member 50 may protect the second electrode layer 15 provided at the second surface of the vibration generating portion 10. According to another aspect of the present disclosure, only one of the first cover member 30 and the second cover member 50 may be configured.

Each of the first cover member 30 and the second cover member 50 according to an aspect of the present disclosure may include one or more materials of plastic, fiber, cloth, paper, leather, rubber, and wood, but aspects of the present disclosure are not limited thereto. For example, each of the first cover member 30 and the second cover member 50 may include the same material or different materials. For example, each of the first cover member 30 and the second cover member 50, made of plastic materials, may be a polyimide film, a polyethylene terephthalate film, or a polyethylene naphthalate film, but aspects of the present disclosure are not limited thereto.

One or more of the first cover member 30 and the second cover member 50 according to another aspect of the present disclosure may include an adhesive member. For example, one or more of the first cover member 30 and the second cover member 50 may include an adhesive member coupled or adhered to the vibration layer 11, and a protection member (or a delamination member) which covers or protects the adhesive member. For example, the adhesive member may include an electrical insulation material which has adhesive properties and is capable of compression and decompression. For example, the first cover member 30 may include an adhesive member coupled or adhered to the vibration layer 11 and a protection member (or a delamination member) which covers or protects the adhesive member.

The adhesive layer 40 may include a first adhesive layer 41 and a second adhesive layer 42. The first cover member 30 may be connected or coupled to at least a portion of the first electrode layer 13 or the first surface of the vibration generating portion 10 by the first adhesive layer 41. For example, the first cover member 30 may be connected or coupled to at least a portion of the first electrode layer 13 or the first surface of the vibration generating portion 10 through a film laminating process using the adhesive layer 40.

The second cover member 50 may be connected or coupled to at least a portion of the second electrode layer 15 or the second surface of the vibration generating portion 10 by the second adhesive layer 42. For example, the second cover member 50 may be connected or coupled to at least a portion of the second electrode layer 15 or the second surface of the vibration generating portion 10 through a film laminating process using the adhesive layer 40.

The adhesive layer 40 according to an aspect of the present disclosure may include an electrical insulation material which has adhesive properties and is capable of compression and decompression. For example, the adhesive layer 40 may include epoxy resin, acrylic resin, silicone resin, and urethane resin, but aspects of the present disclosure are not limited thereto.

The vibration device 20 according to an aspect of the present disclosure may further include a signal cable 90.

The signal cable 90 may be implemented to be connected to the vibration generating portion 10 at one side or a portion of the vibration generating portion 10. The signal cable 90 may be connected to the vibration generating portion 10, between the first cover member 30 and the second cover member 50.

An end portion (or a distal end portion) of the signal cable 90 may be disposed at or inserted (or accommodated) into a portion between one periphery portion of the first cover member 30 and one periphery portion of the second cover member 50. The one periphery portion of the first cover member 30 and the one periphery portion of the second cover member 50 may accommodate or vertically cover a portion of the signal cable 90. Accordingly, the signal cable 90 may be provided as one body with the vibration generating portion 10. For example, the vibration apparatus according to an example aspect of the present disclosure may be a vibration apparatus which is provided as one body with the signal cable 90. For example, the signal cable 90 may be configured as a flexible cable, a flexible printed circuit cable, a flexible flat cable, a single-sided flexible printed circuit, a single-sided flexible printed circuit board (PCB), a flexible multilayer printed circuit, or a flexible multilayer PCB, but aspects of the present disclosure are not limited thereto.

The signal cable 90 according to an aspect of the present disclosure may include a base member 91 and a plurality of signal lines 92a and 92b. For example, the plurality of signal lines 92a and 92b may include a base member 91, a first signal line 92a, and a second signal line 92b.

The base member 91 may include a transparent or an opaque plastic material. For example, the base member 91 may include one or more of synthetic resins such as fluorine resin, polyimide-based resin, polyurethane-based resin, polyester-based resin, polyethylene-based resin, and polypropylene-based resin, but aspects of the present disclosure are not limited thereto. The base member 91 may be a base film or a base insulation film, but aspects of the present disclosure are not limited thereto.

The base member 91 may have a certain width in a first direction X and may extend lengthwise along the second direction Y intersecting with the first direction X.

Each of the first and second signal lines 92a and 92b may be disposed at or on a first surface of the base member 91 in parallel with the second direction Y, and may be spaced apart from or separated from each other along the first direction X. Each of the first and second signal lines 92a and 92b may be arranged in parallel at or on the first surface of the base member 91. For example, each of the first and second signal lines 92a and 92b may be implemented in a line shape by patterning of a metal layer (or a conductive layer) which is formed or deposited at or on the first surface of the base member 91.

A first signal line 92a may be configured at a lower surface of a first electrode layer 13. The first electrode layer 13 may contact the first signal line 92a. The first electrode layer 13 may be electrically connected to the first signal line 92a.

A second signal line 92b may be configured at an upper surface of a second electrode layer 15. The second electrode layer 15 may contact the second signal line 92b. The second electrode layer 15 may be electrically connected to the second signal line 92b.

End portions (or distal end portions) of each of the first and second signal lines 92a and 92b may be separated from each other, and thus, may be individually bent or curved.

The end portion (or the distal end portion) of the first signal line 92a may be electrically connected to at least a portion of the first electrode layer 13 of the vibration generating portion 10, at one edge of the first cover member 30. For example, the end portion (or the distal end portion) of the first signal line 92a may be electrically connected to at least a portion of the first electrode layer 13 of the vibration generating portion 10. For example, the end portion (or the distal end portion) of the first signal line 92a may be directly connected to or in direct contact with the first electrode layer 13 of the vibration generating portion 10. Accordingly, the first signal line 92a may supply a driving signal, supplied from a vibration driving circuit, to the first electrode layer 13 of the vibration generating portion 10. For example, the driving signal may be an alternating current (AC) signal.

The end portion (or the distal end portion) of the second signal line 92b may be electrically connected to at least a portion of the second electrode layer 15 of the vibration generating portion 10, at one edge of the second cover member 50. For example, the end portion (or the distal end portion) of the second signal line 92b may be electrically connected to at least a portion of the second electrode layer 15 of the vibration generating portion 10. For example, the end portion (or the distal end portion) of the second signal line 92b may be directly connected to or in direct contact with the second electrode layer 15 of the vibration generating portion 10. Accordingly, the second signal line 92b may supply a driving signal, supplied from a vibration driving circuit, to the second electrode layer 15 of the vibration generating portion 10. For example, the driving signal may be supplied to the first signal line 92a and the second signal line 92b.

In the vibration generating portion 10, the first electrode layer 13 may receive the driving signal through or by the first signal line 92a, and the second electrode layer 15 may receive the driving signal through or by the second signal line 92b. Accordingly, the vibration generating portion 10 may alternately repeat contraction and/or expansion based on an inverse piezoelectric effect which is generated in the vibration layer 11 based on the driving signal, and thus, may vibrate (or displace or drive).

The signal cable 90 according to an aspect of the present disclosure may further include an insulation member 93.

The insulation member 93 may be disposed at the first surface of the base member 91 to cover each of the first and second signal lines 92a and 92b other than the end portion of the signal cable 90. The insulation member 93 may be a protection layer, a coverlay, a coverlay layer, a cover film, an insulation film, or a solder mask, but aspects of the present disclosure are not limited thereto.

The signal cable 90 or the base member 91 may include a first extension portion 91a which supports an end portion of the first signal line 92a. The first extension portion 91a may extend in the second direction Y from an end of the base member 91 covering the first signal line 92a disposed at the base member 91, and thus, may support the first signal line 92a. The first signal line 92a may be disposed at a lower surface (or a bottom surface) of the first extension portion 91a so as to be directly connected to the vibration generating portion 10.

The signal cable 90 or the base member 91 may include a second extension portion 91b which individually supports an end portion of the second signal line 92b. The second extension portion 91b may extend in the second direction Y from an end of the base member 91, and thus, may support the second signal line 92b. The second signal line 92b may be disposed at a lower surface (or a bottom surface) of the second extension portion 91b so as to be directly connected to the vibration generating portion 10.

The signal cable 90 may include the first and second extension portions 91a and 91b which respectively support the end portions of each of the first and second signal lines 92a and 92b separated from each other. For example, the first and second extension portions 91a and 91b may be separated from each other between the one periphery portion of the first cover member 30 and the one periphery portion of the second cover member 50. Accordingly, the end portions (or distal end portions) of the first and second signal lines 92a and 92b may be separated from each other, and thus, may be individually bent or curved.

According to another aspect of the present disclosure, each of the first and second extension portions 91a and 91b of the signal cable 90 may be omitted. For example, the first and second signal lines 92a and 92b may protrude or extend in a finger shape from the base member 91 of each of the first and second signal lines 92a and 92b, and may be electrically connected to or contact corresponding electrode layers 13 and 15 between the one periphery portion of the first cover member 30 and the one periphery portion of the second cover member 50, respectively. For example, the end portions of each of the first and second signal lines 92a and 92b may be electrically connected to or contact the corresponding electrode layers 13 and 15 by a double-sided tape, and thus, an adhesive force to the corresponding electrode layers 13 and 15 may be secured.

The end portion (or the distal end portion) of the signal cable 90 inserted (or accommodated) between the first cover member 30 and the second cover member 50 may be inserted (or accommodated) and fixed between the first cover member 30 and the second cover member 50 through a film laminating process which uses a first adhesive layer 41 formed in the first cover member 30 and a second adhesive layer 42 formed in the second cover member 50. Therefore, the first signal line 92a may be maintained with being electrically connected to the first electrode layer 13 of the vibration generating portion 10, and the second signal line 92b may be maintained with being electrically connected to the second electrode layer 15 of the vibration generating portion 10. Furthermore, the end portion (or the distal end portion) of the signal cable 90 may be inserted (or accommodated) and fixed between the first cover member 30 and the second cover member 50, and thus, a connection defect between the vibration generating portion 10 and the signal cable 90 caused by movement of the signal cable 90 may be prevented.

In the vibration apparatus according to an aspect of the present disclosure, the first and second signal lines 92a and 92b of the signal cable 90 may be connected to the electrode layer of the vibration generating portion 10 between the first cover member 30 and the second cover member 50, and thus, a soldering process for an electrical connection between the vibration generating portion 10 and the signal cable 90 may not be needed, thereby simplifying a structure and a manufacturing process. Furthermore, according to an example aspect of the present disclosure, a manufacturing process may be simplified, and thus, process optimization may be realized by reducing production energy.

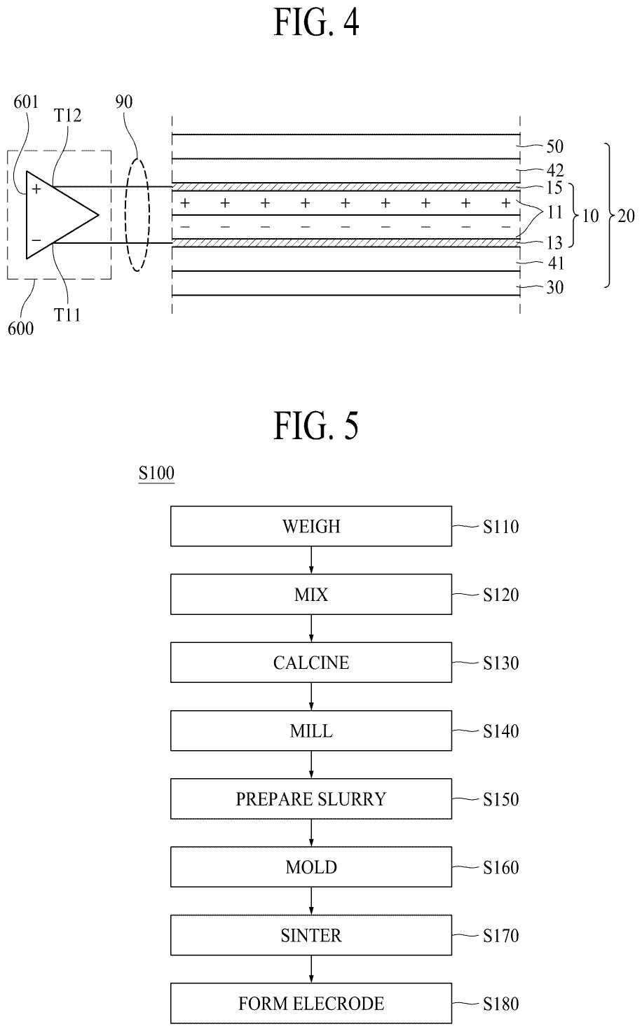

FIG. 4 is a diagram illustrating a driving circuit according to an aspect of the present disclosure. FIG. 4 illustrates a driving circuit connected to the vibration apparatus illustrated in FIGS. 1 to 3.

As shown in FIGS. 1 to 4, an aspect of the present disclosure may further include a driving circuit 600 which supplies a driving signal to the vibration apparatus 20. The driving circuit 600 may be electrically connected to the vibration apparatus 20 and may generate the driving signal based on a sound source to supply to the vibration apparatus 20, and thus, may vibrate or displace the vibration apparatus 20.

The driving circuit 600 according to the present disclosure may include an amplifier 601 which is connected to the vibration generating portion 10 configuring the vibration apparatus 20. The amplifier 601 may generate an AC-type driving signal including a first vibration driving signal and a second vibration driving signal, based on the sound source. The amplifier 601 may output an AC signal to the vibration generating portion 10. For example, the amplifier 601 according to an aspect of the present disclosure may apply an AC signal of 0 V or more to the vibration generating portion 10. For example, the amplifier 601 may include a first output terminal T11 which outputs the first vibration driving signal and a second output terminal T12 which outputs the second vibration driving signal.

In the amplifier 601, the first output terminal T11 may be electrically connected to the first electrode layer 13 of the vibration generating portion 10. The second output terminal T12 may be electrically connected to the second electrode layer 15 of the vibration generating portion 10. For example, the first output terminal T11 of the amplifier 601 may be electrically connected to the first electrode layer 13 of the vibration generating portion 10, and the second output terminal T12 of the amplifier 601 may be electrically connected to the second electrode layer 15 of the vibration generating portion 10. For example, the first vibration driving signal output from the first output terminal T11 of the amplifier 601 may be supplied to the first electrode layer 13 through the first signal line 92a and a flexible signal cable 90 of the vibration generating portion 10. The second vibration driving signal output from the second output terminal T12 of the amplifier 601 may be supplied to the second electrode layer 15 through the second signal line 92b and the flexible signal cable 90 of the vibration generating portion 10.

For example, when the first vibration driving signal output from the first output terminal T11 of the amplifier 601 is 0 V, the second vibration driving signal output from the second output terminal T12 of the amplifier 601 may be the peak voltage Vp. For example, when the second vibration driving signal output from the second output terminal T12 of the amplifier 601 is 0 V, the first vibration driving signal output from the first output terminal T11 of the amplifier 601 may be the peak voltage Vp. For example, the peak voltage Vp according to an aspect of the present disclosure may have a value which is greater than or equal to the coercive field Ec of a piezoelectric material. For example, the peak voltage Vp of the AC signal may have a value which is greater than or equal to the coercive field Ec of the piezoelectric material. For example, the coercive field Ec of the piezoelectric material included in the vibration layer 11 according to an aspect of the present disclosure may have a range of 1.8 kV/cm to 2.3 kV/cm. Accordingly, the peak voltage Vp of the vibration layer 11 according to an aspect of the present disclosure may be 40 Vp to 60 Vp.

An aspect of the present disclosure may use a lead-free BT-based piezoelectric material as the vibration layer 11 so as to replace lead (Pb) and may drive the vibration apparatus by using the unipolar driving method with an AC signal of 0 V or more, and thus, may prevent driving reliability from being reduced due to the low curie temperature Tc and the coercive field Ec. Also, an aspect of the present disclosure may drive the vibration apparatus by using the unipolar driving method with the AC signal of 0 V or more and may set the peak voltage Vp of the AC signal to a value which is greater than or equal to the coercive field Ec of the piezoelectric material, and thus, may enhance a sound pressure level of the vibration apparatus and may enable the self-poling of a sound pressure level.

FIG. 5 is a diagram illustrating a method of manufacturing a vibration apparatus according to an aspect of the present disclosure. This relates to a method of manufacturing the vibration apparatus described above with reference to FIGS. 1 to 3 by a tape casting method. The tape casting method may be a method of molding and sintering a material with a sheet having ductility.

As shown in FIG. 5, a method S100 of manufacturing a vibration apparatus including a piezoelectric material composition according to an aspect of the present disclosure may include a step S110 of weighing the raw materials, a step S120 of mixing the weighed raw materials, a calcination and synthesis step S130 of synthesizing the mixed raw materials, a step S140 of milling a synthesized matrix material, a step S150 of preparing a slurry, a step S160 of press-molding the slurry, a step S170 of sintering the molding element to prepare the sintered element, and a step S180 of forming an outer electrode on the sintered element.

For example, a method of manufacturing a piezoelectric material composition according to one or more aspect of the present disclosure may start from mixing raw materials having Equation 1. In the following description, a condition based on the method of manufacturing the piezoelectric material composition may include, for example, a temperature, pressure, and a time, but aspects of the present disclosure are not limited thereto.

First, the step S110 of weighing the raw materials may be a weighing a raw material on the basis of a mole ratio to add an appropriate amount of solvent.

The piezoelectric material composition of the piezoelectric device according to an aspect of the present disclosure may be expressed as the following Equation 1.

$$a Ba ( {Ti}_{1 - y} , {Zr}_{y} ) {O}_{3 - b} ( {Ba}_{1 - x} , {Ca}_{x} ) {TiO}_{3} + c mol \% A \qquad [ Equation 1 ]$$

For example, A may be TiO₂, CuO, KF, FeO₃, or NiO, 0.40≤a≤0.60, 0.40≤b≤0.60, 0.00<c≤1.00, 0.05≤x≤0.30, and 0.10≤y≤0.20.

A raw material of piezoelectric material composition satisfying Equation 1 may include barium zirconate (BaZrO₃), calcium carbonate (CaCO₃), barium carbonate (BaCO₃), titanium oxide (TiO₂), copper oxide (CuO), potassium fluoride (KF), iron oxide (Fe₂O₃), and nickel oxide. For example, the step S110 of weighing the raw materials may be process which weighs the raw materials on the basis of a mole ratio of a composition to synthesize, puts the weighed raw materials into a nylon jar, and adds an appropriate amount of solvent (for example, ethanol), but aspects of the present disclosure are not limited thereto.

The matrix material according to an aspect of the present disclosure may include Fe₂O₃. For example, Fe₂O₃ may be added by 1 mol % or less. For example, Fe₂O₃ may be added by 0.5 mol %. Accordingly, according to an aspect of the present disclosure, Fe₂O₃ may be added, and thus, the sinterability of a piezoelectric material may more increase.

Subsequently, the step S120 of mixing the raw materials may be mixing and milling the weighed raw material and ethanol by a ball milling process. The weighed raw materials and ethanol may be put into Nalgene bottle along with zirconia ball (for example, yittria stabilized zirconia (YSZ) ball) and ethanol and may be milled. For example, milling may be wet milling, but aspects of the present disclosure are not limited thereto. For example, a ball milling process may be performed for 12 hours to 36 hours within a range of 100 rpm to 150 rpm, but aspects of the present disclosure are not limited thereto.

An aspect of the present disclosure may further include a drying step of separating a powder mixed with the solvent after the mixing step. Here, the drying step may separate and discharge the milled raw material from the ball, and then, may put the mixed raw material into a dish and may dry the mixed raw material at a temperature of 90° C. to 100° C. For example, drying may be performed for 3 hours, but aspects of the present disclosure are not limited thereto. Accordingly, ethanol mixed with the raw material may be removed.

Subsequently, an aspect of the present disclosure may include a step S130 of calcining the raw materials. The step S130 of calcining the raw materials may be phase-synthesizing primarily mixed raw materials. The phase-synthesizing step S130 may include a step of finely grinding a dried compound with a mortar after mixing is completed, and a step of heat treatment in an electric furnace after being placed into an alumina crucible. For example, the calcination temperature may be 1000° C. to 1200° C. and a maintenance time may be 3 hours to 6 hours, but aspects of the present disclosure are not limited thereto. For example, an aspect of the present disclosure may further include a step cooling or natural cooling to room temperature after calcination. Accordingly, in an aspect of the present disclosure, carbonate of the raw materials may be removed, and the raw materials may uniformly react to form a uniform perovskite phase.

Subsequently, the step S140 of milling the matrix material on which calcination ends may be putting the matrix material into Nalgene bottle along with YSZ ball and a solvent (ethanol) and milling the matrix material by a ball milling process to form small particles, but aspects of the present disclosure are not limited thereto. A milling process may be performed for 24 hours within a range of 100 rpm to 150 rpm, but aspects of the present disclosure are not limited thereto.

Moreover, the milling step may further include a drying step of separating a powder mixed with the solvent after the milling step. Here, the drying step may separate and discharge the milled raw material from the ball, and then, may put the milled matrix material into a dish and may dry the milled matrix material at a temperature of 90° C. to 100° C. For example, drying may be performed for 3 hours, but aspects of the present disclosure are not limited thereto.

According to an aspect of the present disclosure, the step S140 of milling a calcination-completed matrix material may further include sieving or granulating a material.

The sieving or granulating step may be filtering out dried powders finely grinded by the mortar by a 40-mesh sieve to produce powders including particles having a certain size or less. A powder passing through the 40-mesh sieve may have a size of 400 μm or less, but aspects of the present disclosure are not limited thereto. For example, the sieving step may be granulating a composition.

Subsequently, the step S150 of preparing the slurry may include performing primary slurry milling on a matrix material, performing secondary slurry milling on the matrix material, and performing tape casting on the matrix material.

The step S150 of preparing the slurry may add an appropriate amount of dispersant and solvent to the matrix material having a composition of Equation 1. For example, the solvent may include one or more of ethanol, methanol, isopropanol, methyl ethyl ketone (MEK), toluene, and distilled water, but aspects of the present disclosure are not limited thereto. By adding an appropriate amount of dispersant and solvent to the matrix material, a slurry where the matrix material is well dispersed in the solvent may be prepared. For example, the step of preparing the slurry may be prepared through a milling step performed twice, but aspects of the present disclosure are not limited to the number of milling steps.

For example, the primary slurry milling may be performed on the prepared matrix material slurry by putting an appropriate amount of solvent and dispersant into Nalgene bottle along with YSZ ball. Such a primary slurry milling step may be dispersing matrix powders. The primary slurry milling may be ball milling, but aspects of the present disclosure are not limited thereto. For example, the primary slurry milling may be performed for 12 hours to 72 hours within a range of 100 rpm to 150 rpm, but aspects of the present disclosure are not limited thereto. For example, the primary slurry milling may be performed for 12 hours in 130 rpm, but aspects of the present disclosure are not limited thereto. For example, the primary slurry milling may be wet milling, but aspects of the present disclosure are not limited thereto.

For example, after the primary slurry milling, the secondary slurry milling may be performed by further adding an appropriate amount of binder and plasticizer. The secondary slurry milling may be mixing and dispersing the binder and the plasticizer in the primary slurry. The secondary slurry milling may be ball milling, but aspects of the present disclosure are not limited thereto. For example, the secondary slurry milling may be performed for 6 hours to 24 hours within a range of 100 rpm to 150 rpm, but aspects of the present disclosure are not limited thereto. For example, the secondary slurry milling may be wet milling, but aspects of the present disclosure are not limited thereto.

An aspect of the present disclosure may further include an aging step and a degassing step of removing an air bubble and a gas after the secondary slurry milling.

The degassing step may be adjusting the slurry to have appropriate viscosity for a molding process and removing an air bubble remaining in the slurry, in a below-described step of molding a piezoelectric material. For example, the degassing step may be adjusted to have a viscosity of 1,000 cPs to 3,000 cPs (centipoise), 1,500 cPs to 2,500 cPs, or 3,000 cPs by a vacuum stirrer at a room temperature, but aspects of the present disclosure are not limited thereto. For example, the degassing step may be adjusted to have a viscosity of 1,700 cPs to 2,400 cPs, or 2,000 cPs (centipoise) by a vacuum stirrer at a room temperature, but aspects of the present disclosure are not limited thereto. Accordingly, an air bubble may be removed in the slurry, and a viscosity may be adjusted by volatilizing a solvent.

The aging step may be adjusting a temperature to a room temperature again because the slurry is cooled when a solvent is volatilized in the degassing step. For example, in the aging step, stirring may be performed for a short time at a low speed of about 10 rpm by the stirrer, but aspects of the present disclosure are not limited thereto. Accordingly, a piezoelectric material having a slurry form may be configured.

Subsequently, a step S160 of press-molding the slurry may be a tape casting step. For example, a tape casting step may be tape-casting a slurry where the matrix material prepared in a previous step is mixed with a seed material, by a tape casting device (or a blade). For example, in a case where tape casting is performed at 90° C. or more, because a evaporation speed of a solvent is fast, a manufactured sheet may be cracked, or a defect such as a void may occur. Therefore, a temperature condition of each period of the tape casting device may be 30° C. to less than 90° C. For example, the tape casting step may be a process where the degassed secondary slurry is put into a slurry chamber, passes through a doctor blade (or a comma blade) adjusted to a certain height at a certain speed (for example, a speed of 0.5 mm/min), and is molded to a green sheet (or a mold sheet) via a temperature period. The temperature period may include a period of 40° C., 60° C., and 80° C., but aspects of the present disclosure are not limited thereto.

Additionally, an aspect of the present disclosure may further include a step S160 of forming an inner electrode. For example, the step of forming the inner electrode may be printing an electrode in the tape-casted green sheet. For example, an inner patterned electrode for manufacturing a multi-layered ceramic application (MLCA) may be printed by a screen printing method. For example, the MLCA may be a multi-layered vibration device. For example, the multi-layered vibration device may include a plurality of vibration devices which are sequentially stacked. Each of the plurality of vibration devices may include a vibration layer including ceramic and an electrode layer which is formed at each of an upper surface and a lower surface of the vibration layer. For example, because each of the plurality of vibration devices is sequentially stacked, an electrode layer may be provided at each of a lowermost surface and an uppermost surface of the multi-layered vibration device, and each of electrode layers may be provided between two adjacent vibration layers of a plurality of vibration layers including ceramic. For example, the other electrode layer (or an electrode layer provided between adjacent vibration layers) except an electrode layer provided at an uppermost surface and an electrode layer provided at a lowermost surface among a plurality of electrode layers may be an inner patterned electrode which is formed by a printing such as screen printing. As another example, in a single-layered ceramic application (SLCA), an inner electrode may not be needed, and thus, a step of printing the inner electrode may be omitted. For example, the SLCA may include one vibration device. For example, one vibration device may include a vibration layer including ceramic and an electrode layer which is formed at each of an upper surface and a lower surface of the vibration layer. For example, in a single-layered ceramic application (SLCA), an inner electrode may not be needed, and thus, a step of printing the inner electrode may be omitted. For example, in the SLCA, an electrode layer may not be provided between vibration layers, and thus, a step of printing the inner electrode may be omitted.

The tape-casted piezoelectric material (or sheet) may be stacked (or laminated), and then, may be pressed for 10 minutes to 30 minutes with pressure of 2,500 psi/cm² to 4,000 psi/cm² at 55° C. to 75° C. For example, the tape-casted piezoelectric material (or sheet) may be stacked, and then, may be pressed for 10 minutes with pressure of 3,000 psi/cm² at 60° C. For example, lamination (or stack) may be stacking prepared green sheets and the green sheets may be stacked with pressure of 100 MPa/cm², but aspects of the present disclosure are not limited thereto.

A step of molding the tape-casted piezoelectric material may be performed through warm isostatic press (WIP). In the piezoelectric material composition according to an aspect of the present disclosure, the WIP may be performed in a case where a molding element is prepared based on stack and lamination such as tape casting. For example, a stacked piezoelectric material may be vacuum-packed by the WIP, and then, may be put into water of 60° C. to 65° C. and may be maintained and pressed with pressure of 3,000 psi/cm² or more for 10 minutes, but aspects of the present disclosure are not limited thereto. The WIP may be thermal isostatic press, but aspects of the present disclosure are not limited thereto.

The step S160 of press-molding the slurry may further include a degreasing step. The degreasing step may be removing a solvent or an organic material. The degreasing step may be firing an organic solvent such as a binder, a plasticizer, or a dispersant before sintering a WIP-completed stack mold sheet. The degreasing step may maintain a molding element in a furnace for 24 hours to 72 hours within a temperature range of 250° C. to 600° C., and then, may cool the molding element up to a room temperature.

Subsequently, the step S170 of sintering the molding element to prepare the sintered element may involve placing the molding element in a furnace, maintaining a molding element in a furnace for 24 hours to 72 hours within a temperature range of 250° C. to 600° C., and then, cooling the molding element up to a room temperature, but aspects of the present disclosure are not limited thereto.

Subsequently, the step S180 of forming the electrode in the sintered element may form the electrode on a first surface of the sintered element of a piezoelectric material, which is prepared in a previous step, and a second surface, which is opposite to the first surface, of the sintered element of the piezoelectric material. For example, the second surface of the sintered element of the piezoelectric material may differ from the first surface, or may be opposite to the first surface. For example, the electrode may include a metal, for example, may be formed by coating metal (for example, silver (Ag)), but aspects of the present disclosure are not limited thereto and the electrode may be used without being limited to a general electrode. For example, the step S170 of forming the electrode in the sintered element may print the electrode in the sintered element by a screen printing, but aspects of the present disclosure are not limited thereto. For example, the step S170 of forming the electrode in the sintered element may include forming the electrode in the sintered element, increasing a temperature up to 600° C. from 400° C. at a temperature increasing speed of 5° C./min and then maintaining the sintered element at 600° C. for 10 minutes to 30 minutes, naturally cooling the sintered element at a room temperature, and applying an electric field of 3 kV/mm at a temperature of 20° C. to 40° C. for about 20 minutes to perform a polarization (or poling) process on the electrode, but aspects of the present disclosure are not limited thereto.

Therefore, a method of manufacturing the vibration driving apparatus according to an aspect of the present disclosure which does not include lead (Pb) and has a high piezoelectric characteristic may be provided.

According to an aspect of the present disclosure, because a piezoelectric material composition does not include Pb, a production restriction material may be reduced and replacement of a harmful material may be implemented, and thus, an environment-friendly piezoelectric material composition may be provided.

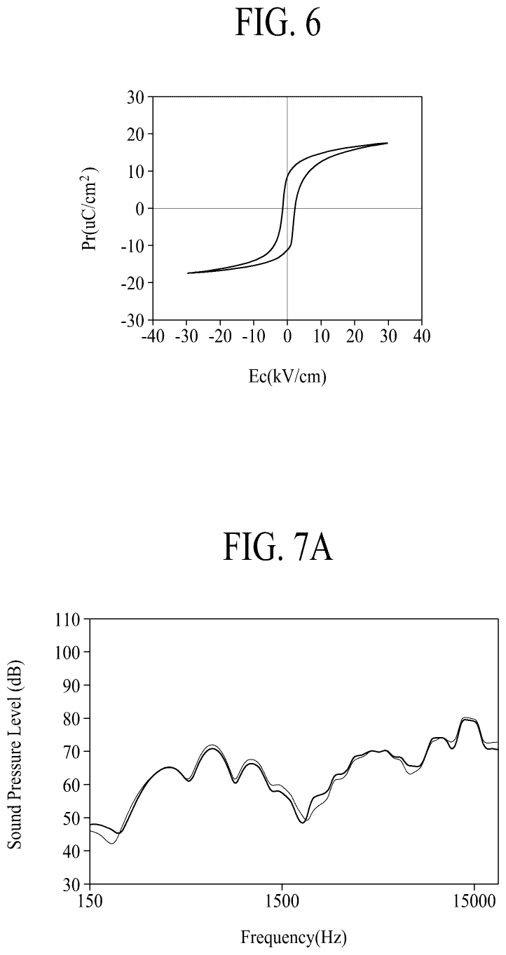

FIG. 6 is a diagram illustrating a graph of an electric field and poling of a vibration apparatus according to an aspect of the present disclosure. This relates to the hysteresis loop of polarization versus electric field of the piezoelectric material according to an aspect of the present disclosure.

As shown in FIG. 6, a coercive field Ec of a vibration layer included in a vibration apparatus according to an aspect of the present disclosure may have a value having a range of 1.8 KV/cm to 2.3 kV/cm.

The inventors have calculated, based on a proportional equation, a voltage of when a thickness of the vibration layer is 150 μm, so as to compare a vibration characteristic of bipolar driving with a vibration characteristic of unipolar driving. For example, a voltage supplied to the vibration layer when a thickness of the vibration layer is 150 μm has been calculated to be a range of about 27.0 V to 34.5 V with reference to FIG. 6. Accordingly, when the coercive field Ec has a range of 1.8 kV/cm to 2.3 kV/cm, a peak voltage Vp of bipolar driving has been calculated to be a range of 13.5 Vp to 17.25 Vp.

The following Table 1 shows vibration accelerations with respect to bipolar driving and unipolar driving of the vibration apparatus according to an aspect of the present disclosure. Table 1 shows vibration accelerations with respect to bipolar driving and unipolar driving including a piezoelectric material composition based on Equation 1 described above with reference to FIGS. 1 to 3. In Table 1, a thickness of the vibration layer has been manufactured to be 150 μm, and a peak voltage Vp of bipolar driving has been set to 12 Vp, 20 Vp, and 30 Vp, based on the coercive field Ec of the piezoelectric material described above. In Table 1, a peak voltage Vp of unipolar driving has been set to 24 Vp, 40 Vp, and 60 Vp, based on the coercive field Ec of the piezoelectric material described above. In Table 1, each of vibration accelerations G_{b} and Gᵤ is a numerical value of a magnitude of a vibration based on each driving method. G_{b}/Gᵤ represents a ratio of a vibration acceleration, occurring in bipolar driving, to a vibration acceleration occurring in unipolar driving.

TABLE 1

| | 200 Hz | | | | | 1000 Hz | | | | |
|---|---|---|---|---|---|---|---|---|---|---|
| | Bipolar | | Unipolar | | | Bipolar | | Unipolar | | |
| | | Vibration | | Vibration | | | Vibration | | Vibration | |
| | Driving | acceler- | Driving | acceler- | | Driving | acceler- | Driving | acceler- | |
| | voltage | ation | voltage | ation | G_{b}/Gᵤ | voltage | ation | voltage | ation | G_{b}/Gᵤ |
| | (V) | (G_{b}) | (V) | (G_{U}) | (%) | (V) | (G_{b}) | (V) | (G_{U}) | (%) |
| Embodiment | −12 V/12 V | 0.41 | 0 V/24 V | 0.44 | 93.1 | −12 V/12 V | 2.23 | 0 V/24 V | 2.44 | 91.4 |
| | −20 V/20 V | 0.57 | 0 V/40 V | 0.70 | 81.4 | −20 V/20 V | 4.08 | 0 V/40 V | 4.67 | 87.4 |
| | −30 V/30 V | 0.98 | 0 V/60 V | 2.08 | 47.1 | −30 V/30 V | 6.43 | 0 V/60 V | 7.80 | 82.4 |

As shown in Table 1, in the vibration apparatus according to an aspect of the present disclosure, in bipolar driving, vibration accelerations of 0.41, 0.57, and 0.98 are respectively shown in −12V/12V, −20V/20V, and −30V/30V. Also, in the vibration apparatus according to an aspect of the present disclosure, in unipolar driving, vibration accelerations of 0.44, 0.70, and 2.08 are respectively shown in 0V/24V, 0V/40V, and 0V/60V.

According to an aspect of the present disclosure, in unipolar driving and bipolar driving of a vibration apparatus, a vibration acceleration has increased as a driving voltage increases.

According to an aspect of the present disclosure, a vibration apparatus shows that a vibration acceleration is higher in unipolar driving than bipolar driving in a peak voltage of 40 Vp or more.

According to an aspect of the present disclosure, a vibration apparatus shows that a vibration acceleration is higher in a case, where a peak voltage Vp has a value (for example, 40 V and 60 V) which is greater than or equal to a coercive field Ec of a piezoelectric material, than a case where the peak voltage Vp has a value (for example, 20 V) which is less than or equal to the coercive field Ec of the piezoelectric material.

Therefore, an aspect of the present disclosure may use a lead-free BT-based piezoelectric material as the vibration layer 11 so as to replace lead (Pb) and may drive the vibration apparatus by using the unipolar driving method with an AC signal of 0 V or more, and thus, may prevent driving reliability from being reduced due to the low curie temperature Tc and the coercive field Ec.

Moreover, an aspect of the present disclosure may drive the vibration apparatus by using the unipolar driving method with the AC signal of 0 V or more and may set the peak voltage Vp of the AC signal to a value which is greater than or equal to the coercive field Ec of the piezoelectric material, and thus, may enhance a sound pressure level of the vibration apparatus and may enable the self-poling of a sound pressure level.

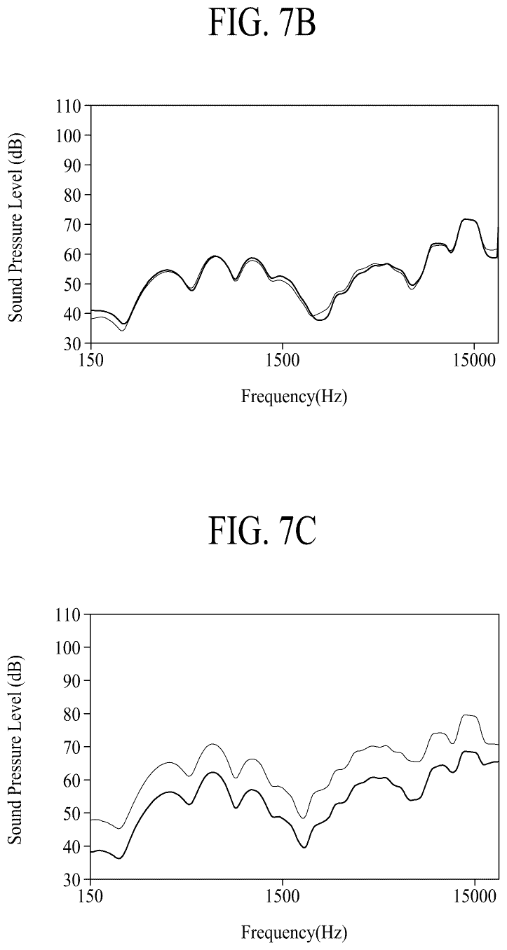

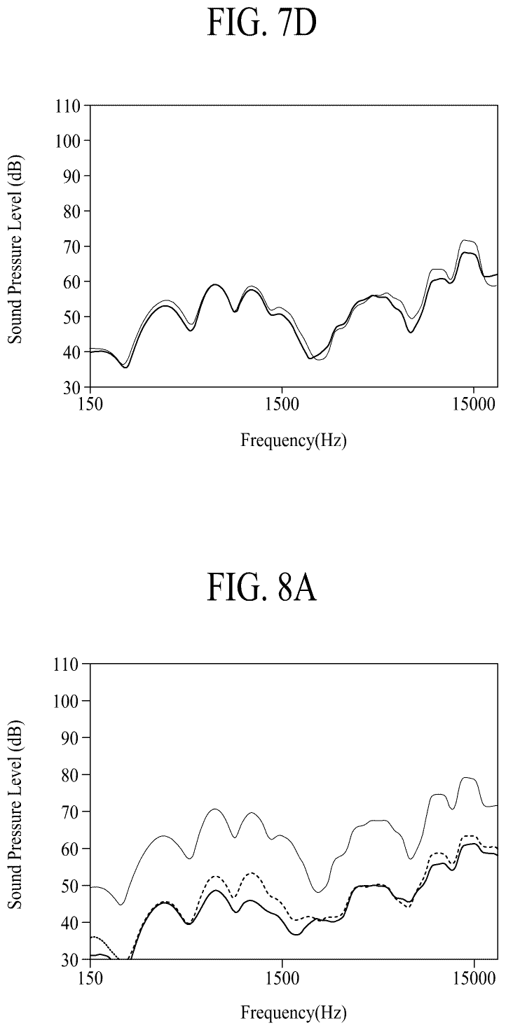

FIGS. 7A to 7D are diagrams illustrating bipolar driving reliability with respect to a temperature of a vibration apparatus according to an experiment example of the present disclosure. In FIGS. 7A to 7D, the horizontal axis represents frequency, and the vertical axis represents sound pressure level.

FIGS. 7A and 7B show a sound pressure level in a case where a vibration apparatus including a BT-based piezoelectric material composition is manufactured as each of a normal device and a degraded device, and bipolar driving is performed for 24 hours at a room temperature. FIGS. 7C and 7D show a sound pressure level in a case where the normal device and the degraded device are driven by bipolar driving for 24 hours at a high temperature. Here, the normal device may be a device after poling is performed in a voltage which is two to three times an Ec value, and the degraded device may be a device after the normal device is depoled for 10 hours or more at the high temperature. For example, a room temperature may be 25° C., and the high temperature may be 60° C. For example, depoling may be a state where a sound pressure level is 80% or less of an initial sound pressure level of the normal device. A driving voltage may be −21.2V/21.2V, and a peak voltage Vp may be 21.2 Vp. For example, 21.2 Vp driving may be a voltage which is less than or equal to a coercive field Ec. In FIGS. 7A and 7B, a thin solid line represents an initial sound pressure level, and a thick solid line represents a sound pressure level after bipolar driving is performed for 24 hours.

As shown in FIG. 7A, in the room temperature, an initial sound pressure level of the normal device is 63.5 dB in a range of 300 Hz to 8 kHz and is 63.5 dB in a range of 150 Hz to 20 kHz. A sound pressure level after the normal device is driven by a bipolar method for 24 hours at the room temperature is 63.5 dB in a range of 300 Hz to 8 kHz and is 63.4 dB in a range of 150 Hz to 20 kHz. Accordingly, in a sound pressure level of the normal device in the room temperature, it may be seen that there is no sound pressure level difference even after bipolar driving.

As shown in FIG. 7B, in the room temperature, an initial sound pressure level of the degraded device is 51.7 dB in a range of 300 Hz to 8 kHz and is 52.3 dB in a range of 150 Hz to 20 kHz. A sound pressure level after the degraded device is driven by the bipolar method for 24 hours at the room temperature is 51.7 dB in a range of 300 Hz to 8 kHz and is 52.5 dB in a range of 150 Hz to 20 kHz. Accordingly, in a sound pressure level of the degraded device in the room temperature, it may be seen that there is no sound pressure level difference even after bipolar driving.

As shown in FIGS. 7A and 7B, it may be seen that a sound pressure level of each of the normal device and the degraded device in the room temperature does not have a difference with an initial sound pressure level even after bipolar driving.

As shown in FIG. 7C, in the room temperature, an initial sound pressure level of the normal device is 63.5 dB in a range of 300 Hz to 8 kHz and is 63.4 dB in a range of 150 Hz to 20 kHz. A sound pressure level after the normal device is driven by the bipolar method for 24 hours at the high temperature is 54.0 dB in a range of 300 Hz to 8 kHz and is 54.1 dB in a range of 150 Hz to 20 kHz. Comparing with an initial sound pressure level, a sound pressure level of the normal device in the high temperature has decreased by about 9.4 dB in a range of 300 Hz to 8 kHz and has decreased by about 9.4 dB in a range of 150 Hz to 20 kHz. Accordingly, in driving of the normal device at the high temperature, it may be seen that a sound pressure level is reduced.

As shown in FIG. 7D, in the room temperature, an initial sound pressure level of the degraded device is 51.7 dB in a range of 300 Hz to 8 kHz and is 52.5 dB in a range of 150 Hz to 20 kHz. A sound pressure level after the degraded device is driven by the bipolar method for 24 hours at the high temperature is 50.8 dB in a range of 300 Hz to 8 kHz and is 51.5 dB in a range of 150 Hz to 20 kHz. Comparing with an initial sound pressure level, a sound pressure level of the degraded device in the high temperature has decreased by about 0.9 dB in a range of 300 Hz to 8 kHz and has decreased by about 1.0 dB in a range of 150 Hz to 20 kHz. Accordingly, it may be seen that a sound pressure level of the degraded device in the high temperature is reduced.

As shown in FIGS. 7C and 7D, comparing with an initial sound pressure level, it may be seen that a sound pressure level of each of the normal device and the degraded device in the high temperature is reduced after bipolar driving. Accordingly, when a vibration apparatus including a BT-based piezoelectric material composition is driven by bipolar driving for 24 hours at the high temperature, it may be seen that a sound pressure level is reduced and driving reliability is reduced.

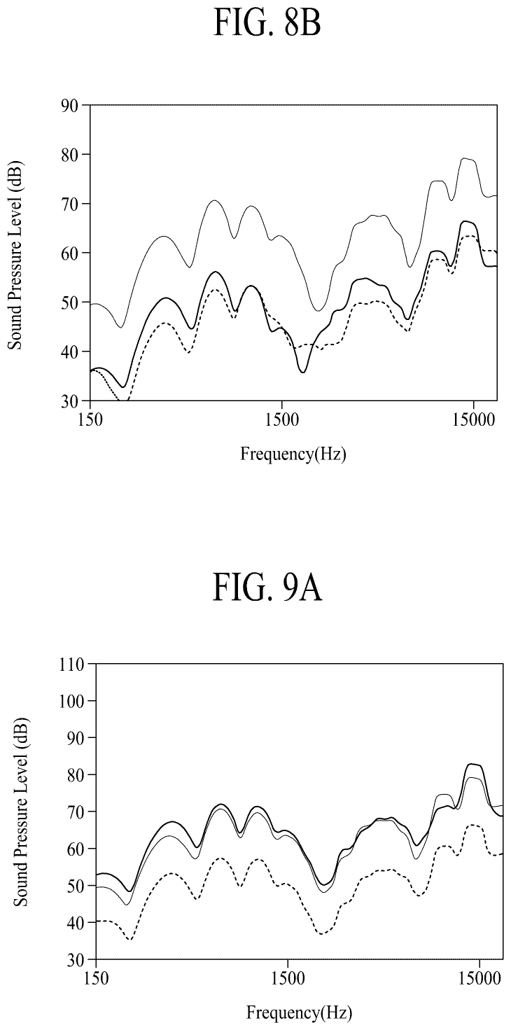

FIGS. 8A and 8B are diagrams illustrating a sound pressure level with respect to a frequency of a vibration apparatus according to an experiment example of the present disclosure. In FIGS. 8A and 8B, the horizontal axis represents frequency, and the vertical axis represents sound pressure level.

According to an experiment example of FIGS. 8A and 8B, a vibration apparatus has been configured to include the piezoelectric material of Equation 1 described above with reference to FIGS. 1 to 3. In FIGS. 8A and 8B, a driving voltage has been set to −20V/20V, and a driving time has been set to 2 hours. A sound output characteristic of the vibration apparatus with respect to a frequency has been measured in an anechoic chamber. Measurement has been performed under a condition where an applied voltage is 5 Vrms and an applied frequency signal is applied as a sine sweep within a range of 20 Hz to 20 kHz, and ⅓ octave smoothing has been performed on a measurement result. A vibration plate has used a SUS plate, and a width, a height, and a thickness of the vibration plate has been prepared to respectively be 30 mm, 30 mm, and 0.5 mm. FIGS. 8A and 8B show results obtained by measuring a sound pressure level with respect to a frequency in 100 Hz and 1 kHz. In FIGS. 8A and 8B, a thin solid line represents an initial sound pressure level in each frequency, a thick solid line represents a sound pressure level in each frequency after being driven by the bipolar method for 2 hours, and a dotted line represents a sound pressure level in each frequency after depoling is performed for 2 hours at 100° C.

The following Equation 2 may be a table which shows an initial sound pressure level, a sound pressure level after depoling, and a sound pressure level after driving with respect to a frequency of a vibration apparatus.

TABLE 2

| | SPL(dB) | | |
|---|---|---|---|
| | Initial sound | | Sound pressure level |
| Frequency | pressure level | Depoling | after driving |
| 100 Hz | 62.80 | 47.07 | 44.89 |
| 1 kHz | 62.80 | 47.07 | 49.50 |

As shown in FIGS. 8A and 8B and Table 2, all initial sound pressure levels have been measured to be 62.80 dB in 100 Hz and 1 kHz. Sound pressure levels after depoling is performed for 2 hours at 100° C. have been measured to be 47.07 dB in 100 Hz and 1 kHz. Sound pressure levels after being driven by the bipolar method for 2 hours have been measured to be 44.89 dB in 100 Hz and 49.50 dB in 1 kHz.

According to the present disclosure, comparing with an initial sound pressure level, it may be seen that sound pressure levels after being driven by the bipolar method for 2 hours decrease by about 18.07 dB in 100 Hz and about 13.38 dB in 1 kHz. Accordingly, in an aspect according to the present disclosure, when a vibration apparatus is driven by the bipolar method, it may be seen that a sound pressure level is reduced compared to the initial sound pressure level.

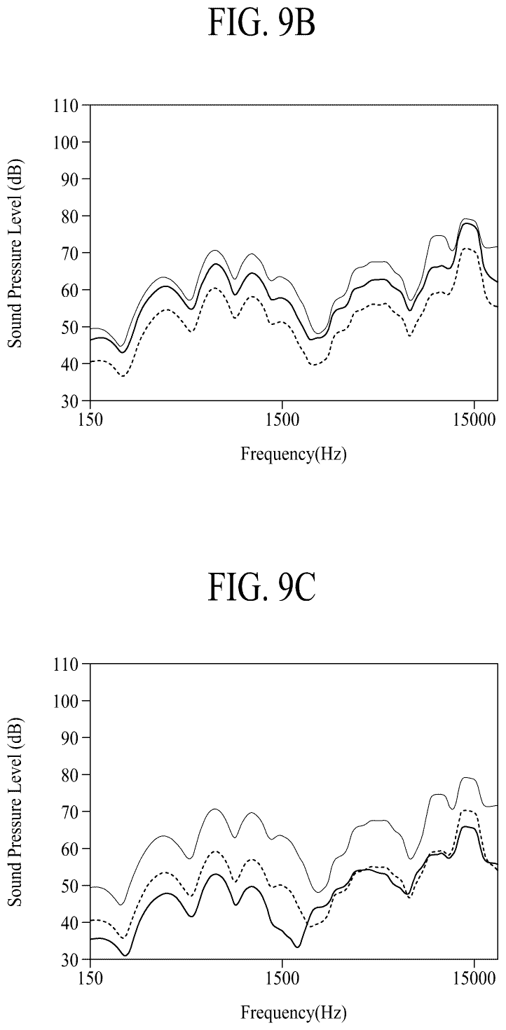

FIGS. 9A to 9C are diagrams illustrating a sound pressure level with respect to a frequency of a vibration apparatus according to an aspect of the present disclosure. In FIGS. 9A to 9C, the horizontal axis represents frequency, and the vertical axis represents sound pressure level.

According to an experiment example of FIGS. 9A and 9B, a vibration apparatus has been configured to include the piezoelectric material of Equation 1 described above with reference to FIGS. 1 to 3. In FIGS. 9A to 9C, a driving voltage has been set to 0V/40V, a peak voltage Vp has been set to 40 Vp, and a driving time has been set to 2 hours. A measurement method of a sound pressure level of the vibration apparatus with respect to a frequency may be the same as the descriptions of FIGS. 8A and 8B. A vibration plate has used a SUS plate, and a width, a height, and a thickness of the vibration plate has been prepared to respectively be 30 mm, 30 mm, and 0.5 mm. FIGS. 9A to 9C show results obtained by measuring a sound pressure level with respect to a frequency in 100 Hz, 1 kHz, and 10 kHz. In FIGS. 9A to 9C, a thin solid line represents an initial sound pressure level in each frequency, a thick solid line represents a sound pressure level in each frequency after being driven by the unipolar method for 2 hours, and a dotted line represents a sound pressure level in each frequency after depoling is performed for 10 hours at 60° C.

The following Table 3 may be a table which shows a sound pressure level with respect to a frequency of a vibration apparatus.

TABLE 3

| | SPL(dB) | | |
|---|---|---|---|
| | Initial sound | | Sound pressure |
| Frequency | pressure level | Depoling | level after driving |
| 100 Hz | 62.8 | 50.63 | 64.45 |
| 1 kHz | 62.8 | 52.36 | 58.90 |
| 10 kHz | 62.8 | 51.56 | 48.87 |

As shown in FIGS. 9A to 9C and Table 3, all initial sound pressure levels have been measured to be 62.80 dB in 100 Hz, 1 kHz, and 10 kHz. Sound pressure levels after depoling is performed for 24 hours at 60° C. have been measured to respectively be 50.63 dB, 52.36 dB, and 51.56 dB in 100 Hz, 1 kHz, and 10 kHz. Sound pressure levels after being driven by the unipolar method for 2 hours have been measured to respectively be 65.45 dB, 58.90 dB, and 47.87 dB in 100 Hz, 1 kHz, and 10 KHz.

According to the present disclosure, comparing with an initial sound pressure level, it may be seen that sound pressure levels after being driven by the unipolar method for 2 hours increase by about 1.65 dB in 100 Hz, decrease by about 3.90 dB in 1 kHz, and decrease by about 14.93 dB in 10 kHz.

Accordingly, in an aspect according to the present disclosure, when a vibration apparatus is driven by the unipolar method, it may be seen that a sound pressure level is recovered to 102% in a low pitched sound band (for example, 100 Hz) and is reduced in a middle-high pitched sound band (for example, 1 kHz to 10 kHz). For example, the reason that a sound pressure level is reduced in the middle-high pitched sound band (for example, 1 kHz to 10 kHz) may be because a vibration apparatus is degraded due to an overcurrent or heat which occurs in the vibration apparatus when being driven with a middle-high pitched sound band signal.

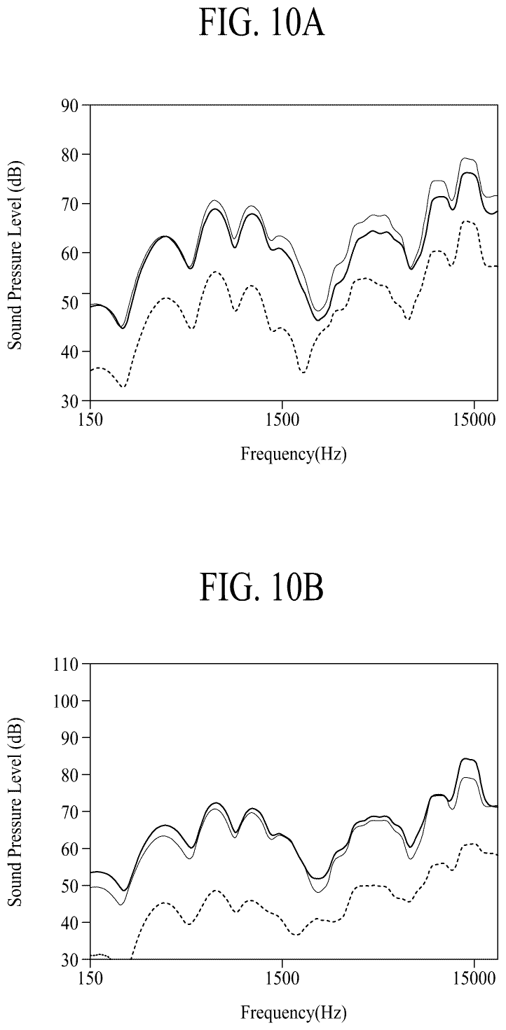

FIGS. 10A and 10B are diagrams illustrating a sound pressure level in a full frequency domain of a vibration apparatus according to an aspect of the present disclosure. FIGS. 10A and 10B are diagrams illustrating a sound pressure level in pink noise.

For example, in a case which measures a sound pressure level of a vibration apparatus, white noise or pink noise is used for evaluating a sound pressure level of a full frequency domain, and in this case, because listening evaluation or reliability evaluation considers the listening capability of a person, pink noise may be used. Therefore, the inventors have evaluated a sound pressure level of the vibration apparatus by using pink noise so as to evaluate a sound pressure level when driving is performed in a full frequency domain. A measurement method of a sound pressure level of the vibration apparatus with respect to a frequency may be the same as the descriptions of FIGS. 8A and 8B. In FIGS. 10A and 10B, an abscissa axis represents a frequency, and an ordinate axis represents a sound pressure level. In FIG. 10A, a driving voltage is 24 V, a peak voltage Vp is 24 V, and a driving time is 2 hours. In FIG. 10B, a driving voltage is 47.5 V, a peak voltage Vp is 47.5 V, and a driving time is 2 hours. In FIGS. 10A and 10B, a thin solid line represents an initial sound pressure level in each frequency, a thick solid line represents a sound pressure level in each frequency after being driven by the unipolar method for 2 hours, and a dotted line represents a sound pressure level in each frequency after depoling is performed for 10 hours at 60° C. In FIG. 10A, the peak voltage Vp has a value which is less than or equal to a coercive field Ec, and in FIG. 10B, the peak voltage Vp has a value which is greater than or equal to the coercive field Ec.

The following Table 4 may be a table which shows a sound pressure level with respect to a frequency of 150 Hz to 20 KHz.

TABLE 4

| | SPL(dB) | | |
|---|---|---|---|
| Peak | Initial sound | | Sound pressure |
| voltage | pressure level | Depoling | level after driving |
| 24 Vp | 62.80 | 49.50 | 60.80 |
| 47.5 Vp | 62.80 | 44.90 | 64.90 |

As shown in FIG. 10A and Table 4, an initial sound pressure level has been measured to be 62.80 dB in a peak voltage Vp of 24 Vp, a sound pressure level after depoling is performed for 10 hours or more at 60° C. has been measured to be 49.50 dB, and a sound pressure level after being driven by the unipolar method for 2 hours has been measured to be 60.80 dB.

Therefore, according to the present disclosure, comparing with the initial sound pressure level, it may be seen that a sound pressure level after being driven by the unipolar method for 2 hours decreases by about 2.0 dB in a peak voltage Vp of 24 Vp.

As shown in FIG. 10B and Table 4, an initial sound pressure level has been measured to be 62.80 dB in a peak voltage Vp of 47.5 Vp, a sound pressure level after depoling is performed for 24 hours at 60° C. has been measured to be 44.90 dB, and a sound pressure level after being driven by the unipolar method for 2 hours has been measured to be 64.90 dB.

Accordingly, in an aspect according to the present disclosure, comparing with the initial sound pressure level, it may be seen that a sound pressure level after being driven by the unipolar method for 2 hours increases by about 2.1 dB in a peak voltage Vp of 47.5 Vp.

Therefore, in an aspect of the present disclosure, in a case where the vibration apparatus is driven by the unipolar driving method with an AC signal of 0 V or more and a peak voltage Vp of the AC signal is set to a value which is greater than or equal to the coercive field Ec of the piezoelectric material, it may be seen that a sound pressure level of the vibration apparatus is enhanced and the self-poling of a sound pressure level is possible.

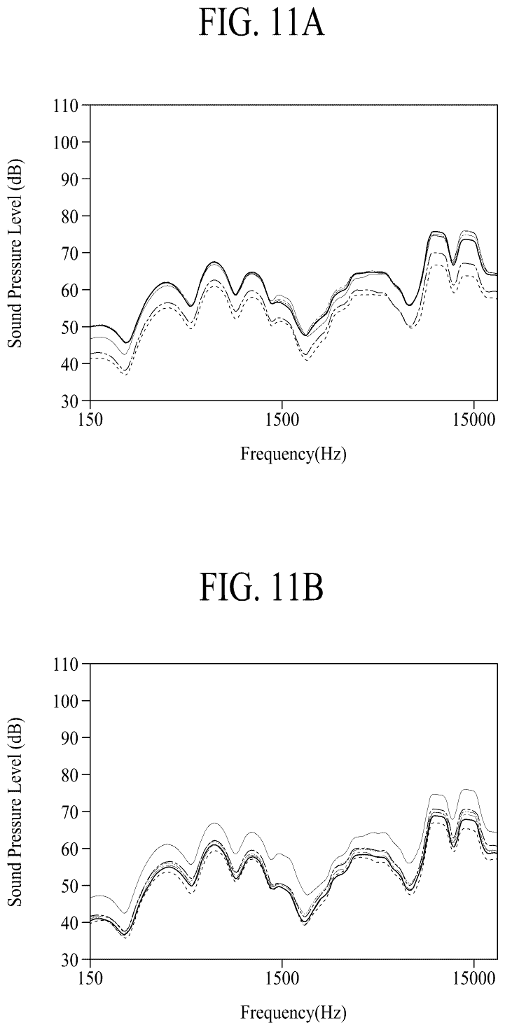

FIGS. 11A and 11B are diagrams illustrating a sound pressure level with respect to a driving time of a piezoelectric device according to an aspect of the present disclosure.

This may be for checking a self-poling effect of a sound pressure level based on a driving voltage, FIG. 11A shows a case where 40 Vp which is a voltage which is greater than or equal to the coercive field Ec is set to a peak voltage Vp, and FIG. 11B shows a case where 24 Vp which is a voltage which is less than or equal to the coercive field Ec is set to a peak voltage Vp. Here, self-poling may denote that a sound pressure level after driving is not reduced compared to an initial sound pressure level and is not recovered. A measurement method of a sound pressure level may be the same as the descriptions of FIGS. 8A and 8B. In FIGS. 11A and 11B, an abscissa axis represents a frequency, and an ordinate axis represents a sound pressure level.

In FIG. 11A, a frequency and a driving voltage have been respectively set to 100 Hz and 40 V, and a driving time has been set to 30 seconds, 1 minute, 3 minutes, and 11 minutes. In FIG. 11A, a thin solid line represents an initial sound pressure level with respect to a frequency, and a dotted line represents a sound pressure level after depoling is performed for 24 hours at 60° C. In FIG. 11A, a thick dash-single dotted line, a thick solid line, a dash-single dotted line, and a dash-double dotted line respectively represent sound pressure levels after being driven for 30 seconds, 1 minute, 3 minutes, and 11 minutes.

In FIG. 11B, a frequency and a driving voltage have been respectively set to 100 Hz and 24 V, and a driving time has been set to 1 minute, 3 minutes, 8 minutes, and 18 minutes. In FIG. 11B, a thin solid line represents an initial sound pressure level with respect to a frequency, and a dotted line 1 represents a sound pressure level after depoling is performed for 24 hours at 60° C. In FIG. 11B, a dotted line 2, a thick solid line, a dash-single dotted line, and a dash-double dotted line respectively represent sound pressure levels after being driven for 1 minute, 3 minutes, 8 minutes, and 18 minutes.

The following Table 5 may be a table which shows a sound pressure level with respect to a frequency of 150 Hz to 20 KHz.

TABLE 5

| | | SLP(dB) | | |
|---|---|---|---|---|
| Peak | Driving time | Initial sound | | Sound pressure |
| voltage | (min) | pressure level | Depoling | level after driving |
| 40 Vp | 0.5 | 59.8 | 53.4 | 55.1 |
| | 1 | 59.8 | — | 60.3 |
| | 3 | 59.8 | — | 60.5 |
| | 11 | 59.8 | — | 60.5 |
| 24 Vp | 1 | 59.8 | 52.3 | 53.4 |
| | 3 | 59.8 | — | 53.9 |
| | 8 | 59.8 | — | 54.6 |
| | 18 | 59.8 | — | 55.1 |

As shown in FIGS. 11A and 11B and Table 5, an initial sound pressure level is 59.8 dB in a peak voltage Vp of 40 Vp and 24 Vp, and a sound pressure level after depoling is performed for 24 hours at 60° C. is 53.4 dB.

As shown in FIG. 11A and Table 5, sound pressure levels of samples which have been driven by the unipolar method for 30 seconds, 1 minute, 3 minutes, and 11 minutes in a peak voltage Vp of 40 Vp have been measured to respectively be 55.1 dB, 60.3 dB, 60.5 dB, and 60.5 dB. Differences between an after-driving sound pressure level and the sound pressure levels of the samples which have been driven by the unipolar method for 30 seconds, 1 minute, 3 minutes, and 11 minutes in the peak voltage Vp of 40 Vp have been measured to respectively be −4.7 dB, 0.5 dB, 0.6 dB, and 0.6 dB. Accordingly, in an aspect of the present disclosure, in a case where the vibration apparatus is driven by the unipolar method for 1 minute or more in 40 Vp which is a peak voltage Vp which is greater than or equal to the coercive field Ec, it may be seen that the self-poling of a sound pressure level is possible.

As shown in FIG. 11B and Table 5, sound pressure levels of samples which have been driven by the unipolar method for 1 minute, 3 minutes, 8 minutes, and 18 minutes in a peak voltage Vp of 24 Vp have been measured to respectively be 53.4 dB, 53.9 dB, 54.6 dB, and 55.1 dB. Differences between an after-driving sound pressure level and the sound pressure levels of the samples which have been driven by the unipolar method for 1 minute, 3 minutes, 8 minutes, and 18 minutes in the peak voltage Vp of 24 Vp have been measured to respectively be −6.4 dB, −5.9 dB, −5.2 dB, and −4.7 dB. Accordingly, in an aspect of the present disclosure, in a case where the vibration apparatus is driven by the unipolar method in 24 Vp which is a peak voltage Vp which is less than or equal to the coercive field Ec, it may be seen that the self-poling of a sound pressure level is not implemented.

Therefore, in an aspect of the present disclosure, in a case where the vibration apparatus is driven by the unipolar driving method with an AC signal of 0 V or more and a peak voltage Vp of the AC signal is set to a value which is greater than or equal to the coercive field Ec of the piezoelectric material, it may be seen that a sound pressure level of the vibration apparatus is enhanced and the self-poling of a sound pressure level is possible.

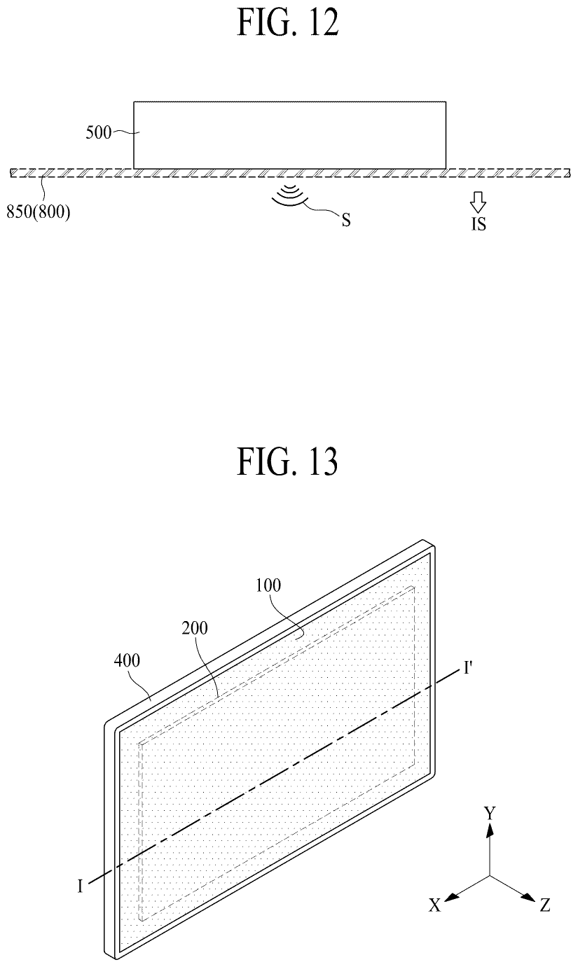

FIG. 12 is a diagram illustrating an automotive sound apparatus according to an aspect of the present disclosure.

As shown in FIG. 12, a vehicular sound apparatus according to an aspect of the present disclosure may include a sound apparatus 500. The sound apparatus 500 may be disposed or equipped in a vehicle so as to output a sound S toward an internal space IS of a vehicle 800.

The vehicle 800 may include an interior material (or an interior finish material) 850. In the following description, for convenience of description, the “interior material 850” may be referred to as a “vehicular interior material 850”.

The vehicular interior material 850 may include all parts configuring the inside of the vehicle 800, or may include all parts disposed at the internal space IS of the vehicle 800. For example, the vehicular interior material 850 may be an interior member or an inner finishing member of the vehicle 800, but aspects of the present disclosure are not limited thereto.

The vehicular interior material 850 according to an aspect of the present disclosure may be configured to be exposed at the internal or indoor space IS of the vehicle 800, in the internal or indoor space IS of the vehicle 800. For example, the vehicular interior material 850 may be provided to cover one surface (or an interior surface) of at least one of a main frame (or a vehicular body), a side frame (or a side body), a door frame (or a door body), a handle frame (or a steering hub), and a seat frame, which are exposed at the indoor space IS of the vehicle 800.

The vehicular interior material 850 according to an aspect of the present disclosure may include a dash board, a pillar interior material (or a pillar trim), a floor interior material (or a floor carpet), a roof interior material (or a headliner), a door interior material (or a door trim), a handle interior material (or a steering cover), a seat interior material, a rear package interior material (or a backseat shelf), an overhead console (or an indoor illumination interior material), a rear view mirror, a glove box, and a sun visor, but aspects of the present disclosure are not limited thereto.

The vehicular interior material 850 according to an aspect of the present disclosure may include one or more of metal, wood, rubber, plastic, glass, fiber, cloth, paper, mirror, leather, and carbon, but aspects of the present disclosure are not limited thereto. The vehicular interior material 850 including a plastic material may be an injection material which is implemented by an injection process using thermosetting resin or thermoplastic resin, but aspects of the present disclosure are not limited thereto. The vehicular interior material 850 including a fiber material may include one or more of synthetic fiber, carbon fiber (or aramid fiber), and natural fiber, but aspects of the present disclosure are not limited thereto. The vehicular interior material 850 including a fiber material may include may be a fabric sheet, a knitting sheet, or a nonwoven fabric, but aspects of the present disclosure are not limited thereto. For example, the interior material 20c or the outer surface member including a fiber material may be a fabric member, but aspects of the present disclosure are not limited thereto. For example, the paper may be cone paper. For example, the cone paper may be pulp or foam plastic, but aspects of the present disclosure are not limited thereto. The vehicular interior material 850 including a leather material may include may be a natural leather or an artificial leather, but aspects of the present disclosure are not limited thereto.

The vehicular interior material 850 according to an aspect of the present disclosure may include one or more of a flat portion and a curved portion. For example, the vehicular interior material 850 may have a structure corresponding to a structure of a corresponding vehicular structure material, or may have a structure which differs from the structure of the corresponding vehicular structure material.

According to an aspect of the present disclosure, the sound apparatus 500 may be disposed at the vehicular interior material 850. The sound apparatus 500 may vibrate the vehicular interior material 850 to generate a sound S, based on a vibration of the vehicular interior material 850. For example, the sound apparatus 500 may directly vibrate the vehicular interior material 850 to generate the sound S, based on a vibration of the vehicular interior material 850.

For example, the sound apparatus 500 may be configured with one of the vibration apparatus according to one or more aspects of the present disclosure described above with reference to FIGS. 1 to 4.

For example, the sound apparatus 500 may be configured to vibrate the vehicular interior material 850 to output the sound S toward the internal or indoor space IS of the vehicle 800. Therefore, the vehicular interior material 850 may be used as a sound vibration plate. The vehicular interior material 850 may be a vibration plate, a sound vibration plate, or a sound generating plate for outputting the sound S. For example, the vehicular interior material 850 may have a size which is greater than that of the sound apparatus 500, but aspects of the present disclosure are not limited thereto.

For example, the sound apparatus 500 may be disposed at one or more of a dash board, a pillar interior material, a floor interior material, a roof interior material, a door interior material, a handle interior material, and a seat interior material, or may be disposed in one or more of a rear package interior material, an overhead console, a rear view mirror, a glove box, and a sun visor.

The sound apparatus 500 according to an aspect of the present disclosure may vibrate a correspond vehicular interior material 850 through at least one of one or more sound apparatuses 500 disposed at the vehicular interior material 850 to output a realistic sound S and/or stereo sound, including a multichannel, toward the indoor space IS of the vehicle 800.

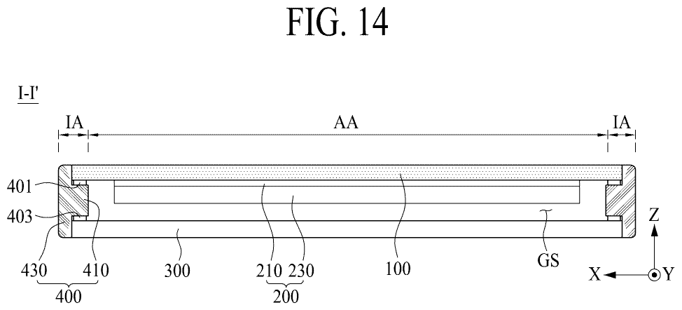

FIG. 13 is a perspective view of a display apparatus according to an aspect of the present disclosure. FIG. 14 is a cross-sectional view taken along line I-I′ illustrated in FIG. 13 according to an aspect of the present disclosure.

As shown in FIGS. 13 and 14, a vibration driving apparatus according to an aspect of the present disclosure may include a vibration member 100 and a piezoelectric device 200.

The vibration member 100 may be configured to display an image. The piezoelectric device 200 may be disposed at a rear surface (or a backside) of the vibration member 100. For example, the piezoelectric device 200 may be configured to vibrate the vibration member 100.

For example, the vibration member 100 may output a sound based on a vibration of the piezoelectric device 200. For example, the vibration member 100 may be a vibration object, a display panel, a vibration plate, or a front member, but aspects of the present disclosure are not limited thereto.

For example, the vibration member 100 or the vibration object may include one or more among a display panel including a pixel configured to display an image, a screen panel on which an image is projected from a display apparatus, a lighting panel, a signage panel, a vehicular interior material, a vehicular glass window, a vehicular exterior material, a building ceiling material, a building interior material, a building glass window, an aircraft interior material, an aircraft glass window, wood, plastic, glass, metal, cloth, fiber, paper, rubber, leather, and a mirror, but aspects of the present disclosure are not limited thereto.

In the following description, the vibration member 100 is a display panel 100 will be described.

The display panel 100 may display an electronic image, a digital image, a still image, or a video image. For example, the display panel 100 may output light to display an image. The display panel 100 may be a curved display panel, or may be any type of display panel, such as a liquid crystal display panel, an organic light emitting display panel, a quantum dot light emitting display panel, a micro light emitting diode display panel, and an electrophoresis display panel, or the like. The display panel 100 may be a flexible display panel. For example, the display panel 100 may a flexible light emitting display panel, a flexible electrophoretic display panel, a flexible electro-wetting display panel, a flexible micro light emitting diode display panel, or a flexible quantum dot light emitting display panel, but aspects of the present disclosure are not limited thereto.

The display panel 100 according to an aspect of the present disclosure may include a display area AA (or an active area) for displaying an image according to driving of the plurality of pixels. Also, the display panel 100 may further include a non-display area IA surrounding the display area AA, but aspects of the present disclosure are not limited thereto.

The piezoelectric device 200 may vibrate the display panel 100 at a rear surface of the display panel 100, thereby providing a sound and/or a haptic feedback based on a vibration of the display panel 100 to a user (or a viewer). The piezoelectric device 200 may be implemented at the rear surface of the display panel 100 to directly vibrate the display panel 100.

As an aspect of the present disclosure, the piezoelectric device 200 may vibrate according to a voice signal synchronized with an image displayed by the display panel 100 to vibrate the display panel 100. As another aspect of the present disclosure, the piezoelectric device 200 may be disposed at the display panel 100, or may vibrate according to a haptic feedback signal (or a tactile feedback signal) synchronized with a user touch applied to a touch panel (or a touch sensor layer) embedded into the display panel 100 to vibrate the display panel 100. Accordingly, the display panel 100 may vibrate based on a vibration of the piezoelectric device 200 to provide a user (or a viewer) with at least one of sound and a haptic feedback.

The piezoelectric device 200 according to an aspect of the present disclosure may be implemented to have a size corresponding to the display area AA of the display panel 100. A size of the piezoelectric device 200 may be 0.9 to 1.1 times a size of the display area AA, but aspects of the present disclosure are not limited thereto. For example, a size of the piezoelectric device 200 may be the same as or smaller than the size of the display area AA. For example, a size of the piezoelectric device 200 may be the same as or approximately same as the display area AA of the display panel 100, and thus, the piezoelectric device 200 may cover a most region of the display panel 100 and a vibration generated by the piezoelectric device 200 may vibrate a whole portion of the display panel 100, and thus, localization of a sound may be high, and satisfaction of a user may be improved. Also, a contact area (or panel coverage) between the display panel 100 and the piezoelectric device 200 may increase, and thus, a vibration region of the display panel 100 may increase, thereby improving a sound of a middle-low-pitched sound band generated based on a vibration of the display panel 100. And, a piezoelectric device 200 applied to a large-sized display apparatus may vibrate the entire display panel 100 having a large size (or a large area), and thus, localization of a sound based on a vibration of the display panel 100 may be further enhanced, thereby realizing an improved sound effect. Therefore, the piezoelectric device 200 according to an aspect of the present disclosure may be disposed at the rear surface of the display panel 100 to sufficiently vibrate the display panel 100 in a vertical (or front-to-rear) direction, thereby outputting a desired sound to a forward region in front of the apparatus or the display apparatus.

The piezoelectric device 200 according to an aspect of the present disclosure may be implemented as a film type. Since the piezoelectric device 200 may be implemented as a film type, it may have a thickness which is thinner than the display panel 100, and thus, a thickness of the display apparatus may not increase due to the arrangement of the piezoelectric device 200. For example, the piezoelectric device 200 may use the display panel 100 as a sound vibration plate. For example, the piezoelectric device 200 may be referred to as a sound generating module, a vibration generating apparatus, a film actuator, a film type piezoelectric composite actuator, a film speaker, a film type piezoelectric speaker, or a film type piezoelectric composite speaker, which uses the display panel 100 as a vibration plate, but aspects of the present disclosure are not limited thereto. As another aspect of the present disclosure, the piezoelectric device 200 may not be disposed at the rear surface of the display panel 100 and may be applied to the vibration object instead of the display panel. For example, the vibration object may be one or more of a non-display panel, wood, metal, plastic, glass, cloth, paper, mirror, fiber, rubber, leather, a vehicle interior material, a vehicle glass window, a building indoor ceiling, a building glass window, a building interior material, an aircraft interior material, and an aircraft glass window, or the like, but aspects of the present disclosure are not limited thereto. For example, the non-display panel may be a light emitting diode lighting panel (or apparatus), an organic light emitting lighting panel (or apparatus), or an inorganic light emitting lighting panel (or apparatus), or the like, but aspects of the present disclosure are not limited thereto. In this case, the vibration object may be applied as a vibration plate, and the piezoelectric device 200 may vibrate the vibration object to output a sound.

The piezoelectric device 200 according to an aspect of the present disclosure may further include a vibration structure 230, a connection member 210 disposed between the vibration structure 230 and the display panel 100. The piezoelectric device 200 according to an aspect of the present disclosure may be the vibration apparatus described with reference to FIGS. 1 to 3, and the vibration structure 230 may be the vibration generating portion described with reference to FIGS. 1 to 3.

According to an aspect of the present disclosure, the connection member 210 may include at least one substrate, and may include an adhesive layer attached to one surface or both surfaces of the substrate, or may be configured as a single layer of adhesive layer.

For example, the connection member 210 may include a foam pad, a double-sided foam pad, a double-sided tape, a double-sided foam tape, a double-sided adhesive, or an adhesive, or the like, but aspects of the present disclosure are not limited thereto. For example, the adhesive layer of the connection member 210 may include epoxy-based, acrylic-based, silicone-based, or urethane-based, but aspects of the present disclosure are not limited thereto.

The display panel 100 according to an aspect of the present disclosure may further include a supporting member 300 disposed at a rear surface of the display panel 100.

The supporting member 300 may cover a rear surface of the display panel 100. For example, the supporting member 300 may cover a whole rear surface of the display panel 100 with a gap space GS therebetween. For example, the supporting member 300 may include at least one or more among a glass material, a metal material, and a plastic material. For example, the supporting member 300 may be a rear structure or a set structure. For example, the supporting member 300 may be a cover bottom, a plate bottom, a back cover, a base frame, a metal frame, a metal chassis, a chassis base, or m-chassis, or the like, but aspects of the present disclosure are not limited thereto. Therefore, the supporting member 300 may be implemented as an arbitrary type frame or a plate-shaped structure disposed at a rear surface of the display panel 100.

The apparatus according to an aspect of the present disclosure may further include a middle frame 400.

The middle frame 400 may be disposed between a rear periphery of the display panel 100 and a front periphery of the supporting member 300. The middle frame 400 may support at least one or more among the rear periphery of the display panel 100 and the front periphery of the supporting member 300, respectively, and may surround one or more of side surfaces among each of the display panel 100 and the supporting member 300. The middle frame 400 may configure a gap space GS between the display panel 100 and the supporting member 300. The middle frame 400 may be referred to as a middle cabinet, a middle cover, a middle chassis, or the like, but aspects of the present disclosure are not limited thereto.

The middle frame 400 according to an aspect of the present disclosure may include a first supporting part 410 and a second supporting part 430.

The first supporting part 410 may be disposed between the rear periphery of the display panel 100 and the front periphery of the supporting member 300, and thus, may configure the gap space GS between the display panel 100 and the supporting member 300. A front surface of the first supporting part 410 may be coupled or connected to the rear periphery of the display panel 100 by a first frame connection member 401. A rear surface of the first supporting part 410 may be coupled or connected to the front periphery of the supporting member 300 by a second frame connection member 403. For example, the first supporting part 710 may have a single picture frame structure having a square shape or a frame structure having a plurality of divided bar shapes, but aspects of the present disclosure are not limited thereto.

The second supporting part 430 may be vertically coupled to an outer surface of the first supporting part 410 in parallel with a thickness direction Z of the apparatus. The second supporting part 430 may surround one or more among an outer surface of the display panel 100 and an outer surface of the supporting member 300, thereby protecting the outer surface of each of the display panel 100 and the supporting member 300. The first supporting part 410 may protrude from an inner surface of the second supporting part 430 toward the gap space GS between the display panel 100 and the supporting member 300.

The apparatus according to an aspect of the present disclosure may be applied to mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic book, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theater apparatuses, theater display apparatuses, TVs, wall paper display apparatuses, signage apparatuses, game apparatuses, notebook computers, monitors, cameras, camcorders, home appliances, or the like. Addition, the vibration apparatus according to some aspects of the present disclosure may be applied to (or included in) organic light emitting lighting apparatuses or inorganic light emitting lighting apparatuses. When the vibration apparatus is applied to (or included in) lighting apparatuses, the lighting apparatuses may act as lighting and a speaker. Addition, when the vibration apparatus of the present disclosure is applied to (or included in) a mobile device, or the like, the vibration apparatus may act as one or more of a speaker, a receiver, and a haptic device, but aspects of the present disclosure are not limited thereto.

A vibration driving apparatus according to one or more aspect of the present disclosure are described below.

A vibration driving apparatus according to one or more aspect of the present disclosure may comprise a vibration member, and a vibration apparatus disposed at a rear surface of the vibration member to vibrate the vibration member according to a driving signal. The driving signal is an alternating current (AC) signal of 0 V or more.

According to one or more aspect of the present disclosure, the vibration driving apparatus may further comprise a driving circuit configured to supply the driving signal to the vibration apparatus. The vibration apparatus may comprise a vibration generating portion including a piezoelectric material, and the driving circuit may comprise an amplifier configured to output the AC signal to the vibration generating portion.

According to one or more aspect of the present disclosure, the vibration generating portion may comprise a vibration layer including a piezoelectric material, a first electrode layer at a first surface of the vibration layer, and a second electrode layer at a second surface, differing from the first surface, of the vibration layer.

According to one or more aspect of the present disclosure, the piezoelectric material may be expressed as Equation 1.

$$a Ba ( {Ti}_{1 - y} , {Zr}_{y} ) {O}_{3 - b} ( {Ba}_{1 - x} , {Ca}_{x} ) {TiO}_{3} + c mol \% A \qquad [ Equation 1 ]$$

where A is TiO₂, CuO, KF, FeO₃, or NiO, 0.40≤a≤0.60, 0.40≤b≤0.60, 0.00<c≤1.00, 0.05≤x≤0.30, and 0.10≤y≤0.20.

According to one or more aspect of the present disclosure, a coercive field of the piezoelectric material may have a range of 1.8 kV/cm to 2.3 kV/cm.

According to one or more aspect of the present disclosure, a peak voltage of the AC signal may have a value which is greater than or equal to the coercive field of the piezoelectric material.

According to one or more aspect of the present disclosure, the peak voltage of the AC signal may be 40 Vp to 60 Vp.

According to one or more aspect of the present disclosure, the amplifier may comprise a first output terminal configured to output a first vibration driving signal, and a second output terminal configured to output a second vibration driving signal.

According to one or more aspect of the present disclosure, the vibration apparatus may comprise a first cover member connected to a first surface of the vibration generating portion, a second cover member connected to a second surface, which is opposite to the first surface, of the vibration generating portion, and a signal cable including a first signal line and a second signal line electrically connected to the vibration generating portion.

According to one or more aspect of the present disclosure, the first output terminal may be electrically connected to the first electrode layer through the first signal line, and the second output terminal may be electrically connected to the second electrode layer through the second signal line.

According to one or more aspect of the present disclosure, the vibration member may comprise one or more of a display panel including a plurality of pixels displaying an image, a screen panel on which an image is projected from a display apparatus, a light emitting diode lighting panel, an organic light emitting lighting panel, an inorganic light emitting lighting panel, a signage panel, an interior material of a vehicular means, an exterior material of a vehicular means, a glass window of a vehicular means, a seat interior material of a vehicular means, a ceiling material of a building, an interior material of a building, a glass window of a building, an interior material of an aircraft, a glass window of an aircraft, wood, plastic, glass, metal, cloth, fiber, paper, rubber, leather, carbon, and a mirror.

The above-described feature, structure, and effect of the present disclosure are included in at least one aspect of the present disclosure, but are not limited to only one aspect. Furthermore, the feature, structure, and effect described in at least one aspect of the present disclosure may be implemented through combination or modification of other aspects by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A vibration driving apparatus, comprising:
a vibration member; and
a vibration apparatus disposed at a rear surface of the vibration member to vibrate the vibration member according to a driving signal,
wherein the driving signal is an alternating current (AC) signal of 0 V or more.

2. The vibration driving apparatus of claim 1, further comprising a driving circuit configured to supply the driving signal to the vibration apparatus,
wherein the vibration apparatus comprises a vibration generating portion including a piezoelectric material, and
wherein the driving circuit comprises an amplifier configured to output the AC signal to the vibration generating portion.

3. The vibration driving apparatus of claim 2, wherein the vibration generating portion comprises:
a vibration layer including a piezoelectric material;
a first electrode layer at a first surface of the vibration layer; and
a second electrode layer at a second surface of the vibration layer, differing from the first surface of the vibration layer.

4. The vibration driving apparatus of claim 3, wherein the piezoelectric material is expressed as Equation 1,
$$a Ba ( {Ti}_{1 - y} , {Zr}_{y} ) {O}_{3 - b} ( {Ba}_{1 - x} , {Ca}_{x} ) {TiO}_{3} + c mol \% A , \qquad ( Equation 1 )$$
where A is TiO₂, CuO, KF, FeO₃, or NiO, 0.40≤a≤0.60, 0.40≤b≤0.60, 0.00<c≤1.00, 0.05≤x≤0.30, and 0.10≤y≤0.20.

5. The vibration driving apparatus of claim 3, wherein a coercive field of the piezoelectric material has a range of 1.8 kV/cm to 2.3 kV/cm.

6. The vibration driving apparatus of claim 5, wherein a peak voltage of the AC signal has a value which is greater than or equal to the coercive field of the piezoelectric material.

7. The vibration driving apparatus of claim 6, wherein the peak voltage of the AC signal is in a range from 40 Vp to 60 Vp.

8. The vibration driving apparatus of claim 3, wherein the amplifier comprises:
a first output terminal configured to output a first vibration driving signal; and
a second output terminal configured to output a second vibration driving signal.

9. The vibration driving apparatus of claim 8, wherein the vibration apparatus comprises:
a first cover member connected to a first surface of the vibration generating portion;
a second cover member connected to a second surface of the vibration generating portion, which is opposite to the first surface of the vibration generating portion; and
a signal cable including a first signal line and a second signal line electrically connected to the vibration generating portion.

10. The vibration driving apparatus of claim 9, wherein:
the first output terminal is electrically connected to the first electrode layer through the first signal line; and
the second output terminal is electrically connected to the second electrode layer through the second signal line.

11. The vibration driving apparatus of claim 1, wherein the vibration member comprises one or more of a display panel including a plurality of pixels displaying an image, a screen panel on which an image is projected from a display apparatus, a light emitting diode lighting panel, an organic light emitting lighting panel, an inorganic light emitting lighting panel, a signage panel, an interior material of a vehicular means, an exterior material of a vehicular means, a glass window of a vehicular means, a seat interior material of a vehicular means, a ceiling material of a building, an interior material of a building, a glass window of a building, an interior material of an aircraft, a glass window of an aircraft, wood, plastic, glass, metal, cloth, fiber, paper, rubber, leather, carbon, and a mirror.
